(19) United States
(12) Patent Application Publication
(10) Pub. No.: US 2016/0342090 A1
(43) Pub. Date: Nov. 24, 2016

(54) ACTINIC RAY-SENSITIVE OR RADIATION-SENSITIVE RESIN COMPOSITION, RESIST FILM, RESIST-COATED MASK BLANK, RESIST PATTERN FORMING METHOD, AND PHOTOMASK

(71) Applicant: FUJIFILM Corporation, Tokyo (JP)

(72) Inventor: Tomotaka TSUCHIMURA, Yoshida-cho (JP)

(73) Assignee: FUJIFILM Corporation, Tokyo (JP)

(21) Appl. No.: 15/229,896

(22) Filed: Aug. 5, 2016

Related U.S. Application Data
(63) Continuation of application No. PCT/JP2015/051293, filed on Jan. 20, 2015.

(30) Foreign Application Priority Data
Feb. 21, 2014 (JP) 2014-031433

(51) Int. Cl. G03F 7/32; G03F 1/76; G03F 7/20; G03F 7/039; G03F 1/50

(52) U.S. Cl. CPC G03F 7/322; G03F 7/039; G03F 1/50; G03F 7/2063; G03F 7/2004; G03F 1/76

(57) ABSTRACT

An actinic ray-sensitive or radiation-sensitive resin composition includes (A) a polymer compound having a structure in which a hydrogen atom of a phenolic hydroxyl group is substituted by a group represented by specific General Formula (I), and (B) a compound capable of generating an acid upon irradiation with actinic rays or radiation.

### CROSS-REFERENCE TO RELATED APPLICATIONS

This application is a Continuation of PCT International Application No. PCT/JP2015/051293 filed on Jan. 20, 2015, which claims priority under 35 U.S.C. §119(a) to Japanese Patent Application No. 2014-031433 filed on Feb. 21, 2014. Each of the above application(s) is hereby expressly incorporated by reference, in its entirety, into the present application.

### BACKGROUND OF THE INVENTION

1. Field of the Invention

The present invention relates to an actinic ray-sensitive or radiation-sensitive resin composition which is suitably used for ultramicrolithographic processes for the production of ultra large scale integrations (ultra LSIs) or high-capacity microchips, or other fabrication processes, and with which high precision patterns can be formed using an electron beam (EB), extreme ultraviolet (EUV) radiation, or the like, as well as a resist film, a resist-coated mask blank, a resist pattern forming method, and a photomask, each using the composition.

2. Description of the Related Art

In microfabrication using a resist composition, formation of an ultrafine pattern is required due to an increase in the integration degree of an integrated circuit. Accordingly, there is an additional tendency that the exposure wavelength becomes shorter, such as from g line to i line, or further to excimer laser light. At present, the development of lithographic techniques using, for example, an electron beam is also proceeding (for example, see JP2013-227433A).

### SUMMARY OF THE INVENTION

Microfabrication using a resist composition is not only used directly in the production of integrated circuits but has also been recently applied to the fabrication or the like of a so-called imprint mold structure. Therefore, it has become an important task to simultaneously provide high resolution (for example, high resolving power, excellent pattern profile, and low line edge roughness (LER)), and good dry etching resistance. There is a need in the art for solutions for these desired requirements.

The present invention has been made in view of the above points. An object of the present invention is to provide an actinic ray-sensitive or radiation-sensitive resin composition which is capable of forming a pattern simultaneously providing high resolution (for example, high resolving power, excellent pattern profile, and low line edge roughness (LER)), and good dry etching resistance, as well as a resist film, a resist-coated mask blank, a resist pattern forming method, and a photomask, each using the composition.

As a result of intensive studies, the present inventors have found that the above-described object can be achieved by using an actinic ray-sensitive or radiation-sensitive resin composition containing a specific polymer compound. The present invention has been completed based on this finding.

That is, the present invention is as follows.

[1] An actinic ray-sensitive or radiation-sensitive resin composition, comprising:

(A) a polymer compound having a structure in which a hydrogen atom of a phenolic hydroxyl group is substituted by a group represented by General Formula (I) described below; and (B) a compound capable of generating an acid upon irradiation with actinic rays or radiation.

[2] The actinic ray-sensitive or radiation-sensitive resin composition according to [1], in which the polymer compound (A) includes a repeating unit represented by General Formula (II) described below.

[3] The actinic ray-sensitive or radiation-sensitive resin composition according to 121, in which the polymer compound (A) includes a repeating unit represented by General Formula (II′) described below.

[4] The actinic ray-sensitive or radiation-sensitive resin composition according to any one of [1] to [3], in which the polymer compound (A) includes a repeating unit represented by General Formula (III) described below.

[5] The actinic ray-sensitive or radiation-sensitive resin composition according to [4], in which the polymer compound (A) includes a repeating unit represented by General Formula (III′) described below.

[6] A resist film formed by the actinic ray-sensitive or radiation-sensitive resin composition according to any one of [1] to [5].

[7] The resist film according to [6], which has a film thickness of 10 nm to 150 nm.

[8] A resist-coated mask blank having the resist film according to [6] or [7] coated thereon.

[9] A resist pattern forming method, comprising:

exposing the resist film according to [6] or [7]; and

developing the exposed resist film.

[10] A resist pattern forming method, comprising:

exposing the resist-coated mask blank according to [8]; and

developing the exposed resist-coated mask blank.

[11] The resist pattern forming method according to [9] or [10], in which the exposure is carried out using an electron beam or extreme ultraviolet rays.

[12] A photomask obtained by exposing and developing the resist-coated mask blank according to [8].

Present invention enables to provide an actinic ray-sensitive or radiation-sensitive resin composition which is capable of forming a pattern simultaneously providing high resolution, and good dry etching resistance, as well as a resist film, a resist-coated mask blank, a resist pattern forming method, and a photomask, each using the composition.

### DESCRIPTION OF THE PREFERRED EMBODIMENTS

Hereinafter, embodiments of the present invention will be described in detail.

In the description of the present invention, when a group (atomic group) is denoted without specifying whether substituted or unsubstituted, the group includes both a group having no substituent and a group having a substituent. For example, “an alkyl group” includes not only an alkyl group having no substituent (unsubstituted alkyl group) but also an alkyl group having a substituent (substituted alkyl group).

Incidentally, the term “actinic rays” or “radiation” as used herein refers to, for example, a bright line spectrum of mercury lamp, far ultraviolet rays represented by excimer laser, extreme ultraviolet rays (EUV light), X-rays, an electron beam, or the like. As used herein, the term “light” means actinic rays or radiation. Furthermore, unless otherwise indicated, the term “exposure” as used herein includes not only exposure to a mercury lamp, far ultraviolet rays represented by excimer laser light, X-rays, EUV light, or the like but also lithography with particle beams such as an electron beam and an ion beam.

The actinic ray-sensitive or radiation-sensitive resin composition of the present invention (hereinafter, simply referred to as “composition” or “composition of the present invention”.) is an actinic ray-sensitive or radiation-sensitive resin composition including (A) a polymer compound having a structure in which a hydrogen atom of a phenolic hydroxyl group is substituted by a group represented by General Formula (I) described below, and (B) a compound capable of generating an acid upon irradiation with actinic rays or radiation.

The composition of the present invention is preferably for electron beam or extreme ultraviolet exposure.

The composition of the present invention may be a negative chemically amplified resist composition or may be a positive chemically amplified resist composition.

A pattern simultaneously providing high resolution (for example, high resolving power, excellent pattern profile, and low line edge roughness (LER)), and good dry etching resistance can be formed by forming a resist film using the composition of the present invention containing a specific polymer compound (A). Although the reason is not clear, it is estimated as follows.

First, a phenolic hydroxyl group of the polymer compound (A) has been protected by a group represented by General Formula (I), but this group contains an alicyclic group having a relatively high glass transition point (Tg). Therefore, it is considered that a Tg of the polymer compound (A) itself, or a Tg of a resist film formed from a composition containing the polymer compound (A) also becomes higher, and as a result, dry etching resistance is improved.

Moreover, it is considered that high resolving power, excellent pattern profile, small LER, and the like are achieved because the diffusion of an acid generated from a later-described compound (B) (acid generator) is inhibited as a Tg becomes higher.

Hereinafter, the actinic ray-sensitive or radiation-sensitive resin composition of the present invention will be described in detail.

[1] (A) Polymer Compound

The actinic ray-sensitive or radiation-sensitive resin composition of the present invention contains (A) a polymer compound having a structure in which a hydrogen atom of a phenolic hydroxyl group is substituted by a group represented by the following General Formula (I) (hereinafter, also referred to as “polymer compound (A)”).

The present invention uses, as a main component, a polymer compound which contains phenolic hydroxyl groups and in which a portion of the phenolic hydroxyl groups is substituted by a group represented by the following General Formula (I).

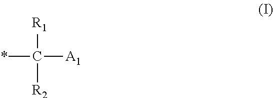

In General Formula (I), A₁ represents an alicyclic group having 3 to 12 carbon atoms which may have a heteroatom. R₁ and R₂ each independently represent a hydrocarbon group. R₁ and R₂ may be bonded to each other to form a ring. * indicates a binding site to an oxygen atom of the phenolic hydroxyl group.

The site which is substituted by a group represented by General Formula (I) is a part having a function of controlling the developability of a polymer compound containing a repeating unit having a phenolic hydroxyl group. The structure in which a hydrogen atom of a phenolic hydroxyl group is substituted by a group represented by General Formula (I) is decomposed by the action of an acid to generate a phenolic hydroxyl group.

The group represented by General Formula (I) will now be described.

In General Formula (I), A₁ represents an alicyclic group having 3 to 12 carbon atoms which may have a heteroatom and which may have a double bond.

Examples of such an alicyclic group include a monocyclic cycloalkyl group and a bridged cycloalkyl group.

Examples of the monocyclic cycloalkyl group include a cyclopropyl group, a cyclobutyl group, a cycloheptyl group, a cyclohexyl group, a cyclopentyl group, a cyclooctyl group, a cyclononyl group, a cyclodenyl group, a cycloundenyl group, and a cyclododecanyl group. The monocyclic cycloalkyl group is preferably a cyclohexyl group or a cyclopentyl group.

The bridged cycloalkyl group is, for example, a group containing a structure such as a bicyclo structure, a tricyclo structure, or a tetracyclo structure, and specific examples thereof include a bicyclobutyl group, a bicyclohexyl group, a bicycloheptyl group, a bicyclooctyl group, a bicyclononyl group, a bicyclodecanyl group, a bicycloundecanyl group, a bicyclododecanyl group, an adamantyl group, a decalin group, an isobornyl group, a norbornyl group, a cedrol group, a camphanyl group, an α-pinel group, a tricyclodecanyl group, a tetracyclododecyl group, and androstanyl group. Among these, preferred are an adamantyl group, a decalin group, a norbornyl group, a cedrol group, a bicyclohexyl group, a bicycloheptyl group, a bicyclooctyl group, a bicyclodecanyl group, a bicyclododecanyl group, and a tricyclodecanyl group. More preferred is an adamantyl group from the viewpoint of dry etching resistance.

Further, other examples of the alicyclic group include a cyclohexenyl group, a cyclohexadienyl group, a cyclopentenyl group, a cyclopentadienyl group, a bicyclooctenyl group, and a bicyclotridecenyl group.

Further, a part of carbon atoms in the monocyclic or bridged cycloalkyl group may be substituted, for example, by a heteroatom such as an oxygen atom or a sulfur atom.

The alicyclic group represented by A₁ is preferably a bridged cycloalkyl group, because the effect of the present invention (in particular, dry etching resistance) is superior.

In General Formula (I), R₁ and R₂ each independently represent a hydrocarbon group. The number of carbon atoms in the hydrocarbon group represented by R₁ and R₂ is preferably 1 to 12, and more preferably 1 to 6.

The hydrocarbon group represented by R₁ and R₂ is preferably an alkyl group, an alkenyl group, an alkynyl group, or an aryl group, more preferably an alkyl group having 1 to 4 carbon atoms, each of which may have a substituent. Examples of the substituent include an alkyl group (preferably having 1 to 6 carbon atoms), a halogen atom, a hydroxyl group, an alkoxy group (preferably having 1 to 6 carbon atoms), a carboxyl group, a carbonyl group, and an alkoxycarbonyl group (preferably having 2 to 7 carbon atoms), preferably an alkyl group and an alkoxy group, and more preferably an alkyl group having 1 to 4 carbon atoms and an alkoxy group having 1 to 4 carbon atoms.

Further, in General Formula (I), R₁ and R₂ may be bonded to each other to form a ring. Examples of the ring which may be formed by R₁ and R₂ include those described for the alicyclic group represented by A₁ described above, and a preferred range thereof is also the same.

The structure in which a hydrogen atom of a phenolic hydroxyl group is substituted by a group represented by General Formula (I) is preferably included in the side chain of a repeating unit represented by the following General Formula (II). That is, the polymer compound (A) preferably includes a repeating unit represented by the following General Formula (II).

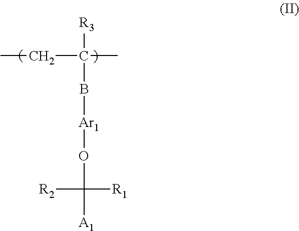

In General Formula (II), A₁ represents an alicyclic group having 3 to 12 carbon atoms which may have a heteroatom. R₁ and R₂ each independently represent a hydrocarbon group. R₁ and R₂ may be bonded to each other to form a ring. Ar₁ represents an arylene group. B represents a single bond or a divalent organic group. R₃ represents a hydrogen atom, a methyl group which may have a substituent, or a halogen atom.

A₁, R₁, and R₂ in General Formula (II) have the same definitions as A₁, R₁, and R₂ in General Formula (I).

In General Formula (II), the arylene group represented by Arₜ is preferably an arylene group having 6 to 18 carbon atoms, more preferably a phenylene group or a naphthylene group, and most preferably a phenylene group.

Further, the arylene group represented by Ar₁ may have a substituent in addition to the group represented by —OC(R₁)(R₂)-A₁, and examples of the substituent include the same substituents as in specific examples and preferred ranges of the substituent which may be substituted on R₁ in General Formula (I).

In General Formula (II), examples of the divalent organic group represented by B include alkylene groups having 1 to 10 carbon atoms, such as a methylene group, an ethylene group, a propylene group, a butylene group, a hexylene group, and an octylene group.

Further, B in General Formula (II) is preferably a single bond.

In General Formula (II), examples of the substituent which may be substituted on a methyl group represented by R₃ include the same substituents as in specific examples and preferred ranges of the substituent which may be substituted on R₁ in General Formula (I)

R₃ in General Formula (II) is preferably a hydrogen atom or a methyl group, and more preferably a hydrogen atom.

The structure in which a hydrogen atom of a phenolic hydroxyl group is substituted by a group represented by General Formula (I) is more preferably included in the side chain of a repeating unit represented by the following General Formula (II′). That is, the polymer compound (A) more preferably includes a repeating unit represented by the following General Formula (II′).

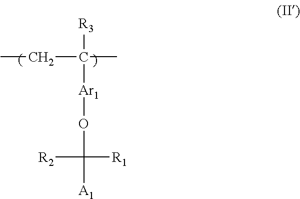

In General Formula (II′), A₁ represents an alicyclic group having 3 to 12 carbon atoms which may have a heteroatom. R₁ and R₂ each independently represent a hydrocarbon group. R₁ and R₂ may be bonded to each other to form a ring. Ar₁ represents an arylene group. R₃ represents a hydrogen atom, a methyl group which may have a substituent, or a halogen atom.

A₁, R₁, R₂, Ar₁, and R₃ in General Formula (II′) have the same definitions as A₁, R₁, R₂, Ar₁, and R₃ in General Formula (II).

Below are shown specific examples of the repeating unit having a structure in which a hydrogen atom of a phenolic hydroxyl group is substituted by a group represented by General Formula (I), or the repeating unit represented by General Formula (II) or (II′). However, the present invention is not limited thereto.

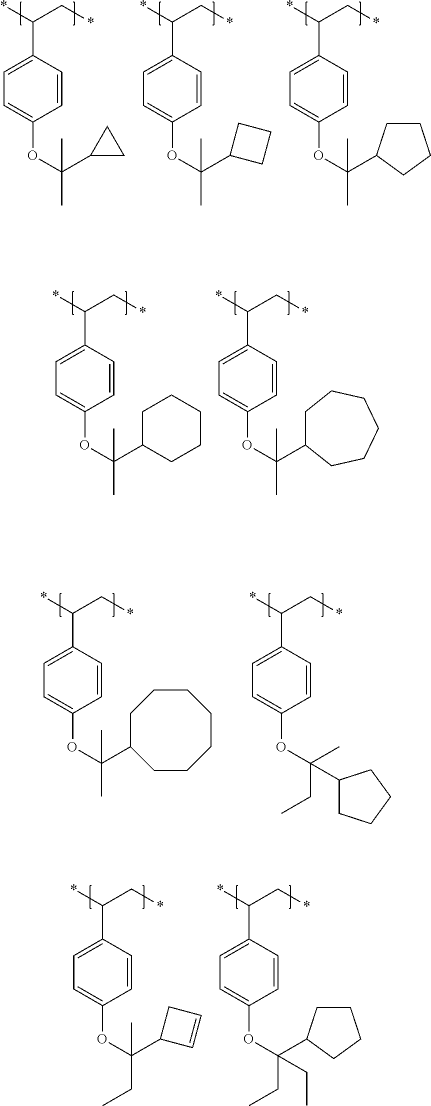

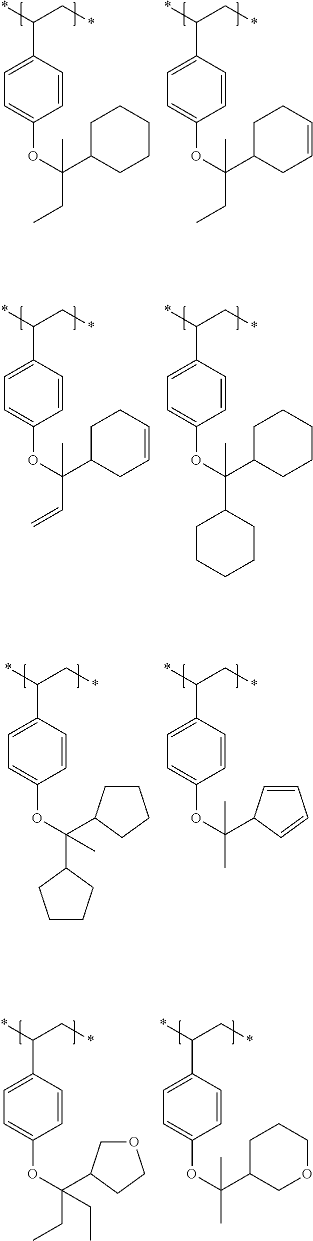

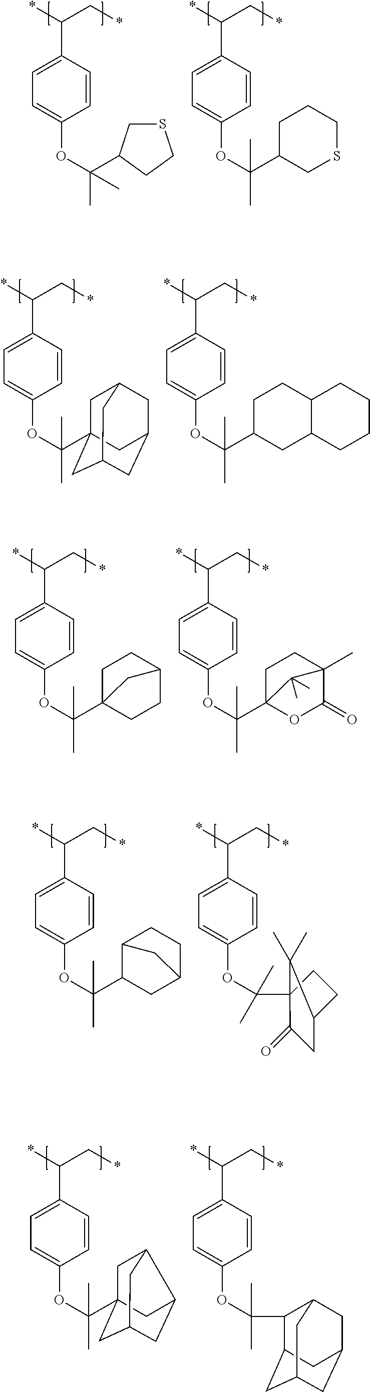

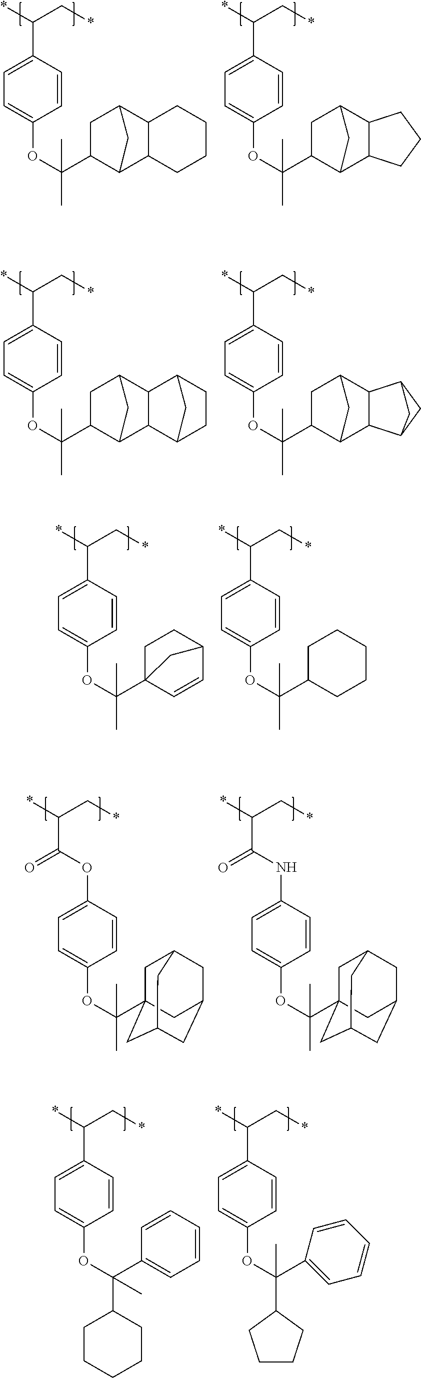

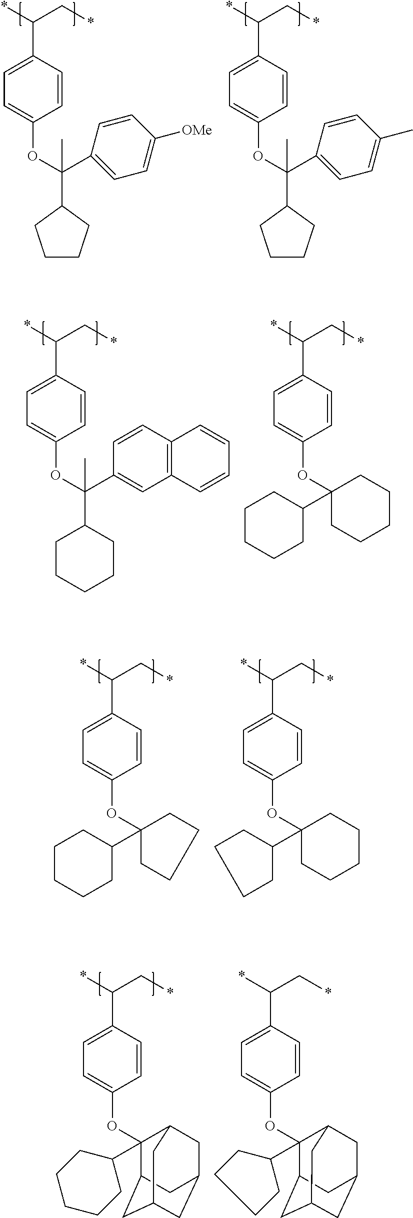

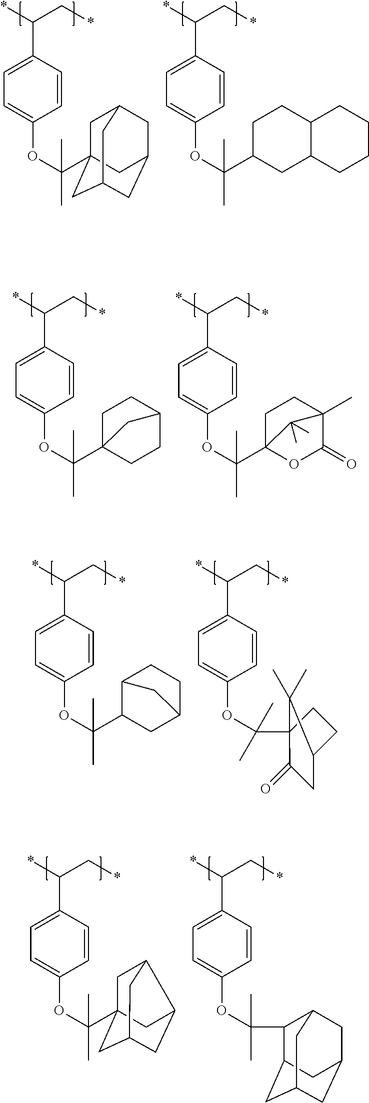

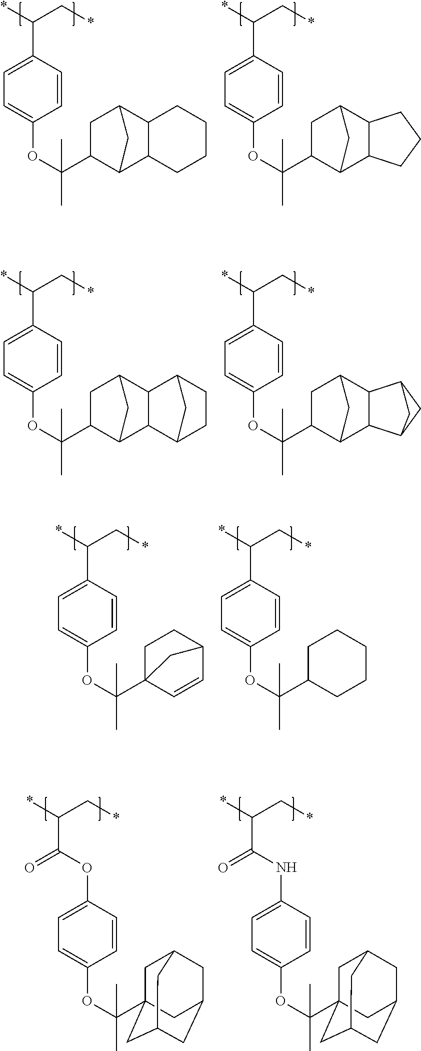

The method for obtaining the repeating unit represented by General Formula (II) includes, for example, but is not limited to, a method of obtaining such a repeating unit from a phenol-containing polymerizable monomer or a phenol-containing polymer, by step i) shown in the following reaction scheme.

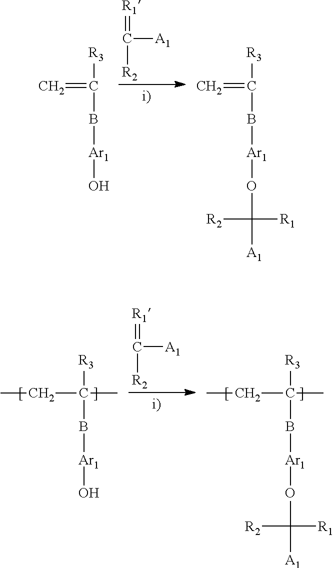

A₁, R₁, R₂, R₃, B, and Ar₁ in the above reaction scheme have the same definitions as A₁, R₁, R₂, R₃, B, and Ar₁ in General Formula (II).

Further, R₁′ in the above reaction scheme represents a group formed by removing a hydrogen atom from the hydrocarbon group represented by R₁ in General Formula (II).

The above reaction proceeds easily in a known condition, but the reaction is preferably carried out by reacting a phenol compound and an olefin compound at a reaction temperature of −30° C. to 50° C., in the absence of a solvent or in the presence of a solvent such as toluene or hexane and in the presence of an acid catalyst. Examples of the acid catalyst to be used include inorganic acids such as hydrochloric acid, sulfuric acid, nitric acid, and perchloric acid; organic acids such as methanesulfonic acid, trifluoromethanesulfonic acid, p-toluenesulfonic acid, and benzenesulfonic acid; Lewis acids such as boron trifluoride; and solid acids such as montmorillonite and amberlite.

The content of the repeating unit having a structure in which a hydrogen atom of a phenolic hydroxyl group is substituted by a group represented by General Formula (I), or the repeating unit represented by General Formula (II) or (II′) in the polymer compound (A) is preferably in the range of 1 mol % to 60 mol %, and more preferably in the range of 3 mol % to 40 mol %, based on the total repeating units of the polymer compound (A).

The polymer compound (A) preferably further includes a repeating unit represented by the following General Formula (III).

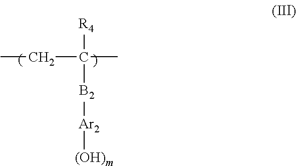

In General Formula (III), R₄ represents a hydrogen atom, a methyl group which may have a substituent, or a halogen atom. B₂ represents a single bond or a divalent organic group. Ar₂ represents an arylene group, m represents an integer of I or more.

In General Formula (III), examples of the substituent which may be substituted on a methyl group represented by R₄ include the same substituents as in specific examples and preferred ranges of the substituent which may be substituted on R₁ in General Formula (I). R₄ in General Formula (II) is preferably a hydrogen atom or a methyl group, and more preferably a hydrogen atom.

In General Formula (III), an arylene group represented by Ar₂ is preferably an arylene group having 6 to 18 carbon atoms, more preferably a phenylene group or a naphthylene group, and most preferably a phenylene group.

Further, the arylene group represented by Ar₂ may have a substituent in addition to the group represented by —(OH)ₘ, and examples of the substituent include the same substituents as in specific examples and preferred ranges of the substituent which may be substituted on R₁ in General Formula (I).

m in General Formula (III) is an integer of 1 or more, preferably an integer in the range of 1 to 5, and more preferably 1.

Further, in General Formula (I), when Ar₂ is a phenylene group and m is 1, the bonding position of —OH with respect to the benzene ring of Ar₂ may be a para-position, a meta-position, or an ortho-position with respect to the bonding position of B₂ with respect to the benzene ring of Ar₂, but is preferably a para-position or a meta-position.

In General Formula (III), examples of the divalent organic group represented by B₂ are the same as in specific examples and preferred ranges of the divalent organic group represented by B in General Formula (II).

The repeating unit represented by General Formula (III) is preferably a repeating unit represented by the following General Formula (III′).

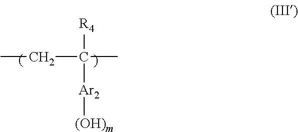

In General Formula (III′), R₄ represents a hydrogen atom, a methyl group which may have a substituent, or a halogen atom. Ar₂ represents an arylene group. m represents an integer of 1 or more.

In General Formula (III′), R₄, Ar₂, and m have the same definitions as R₄, Ar₂, and m in General Formula (III).

The repeating unit represented by General Formula (III) is a repeating unit having an alkali-soluble group and has a function of controlling the developability of a resist film.

Preferred examples of the repeating unit represented by General Formula (III) are described below.

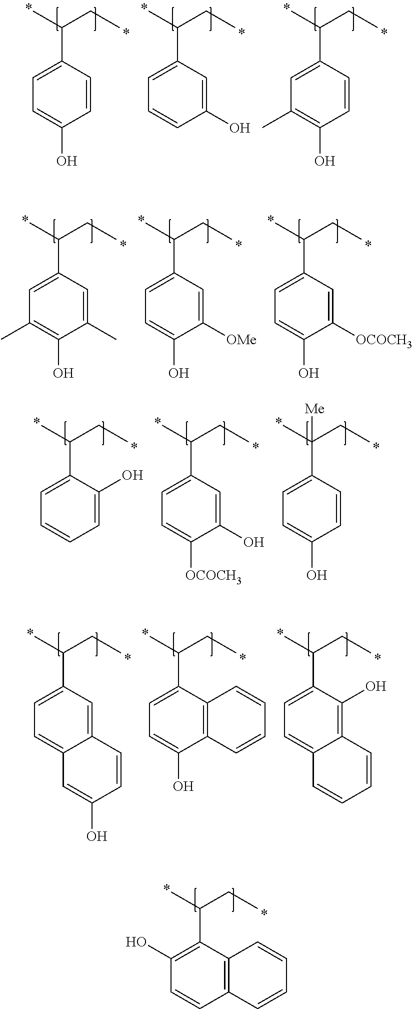

Among these, preferred examples of the repeating unit represented by General Formula (III) are repeating units in which Ar₂ is an unsubstituted phenylene group, and include those described below.

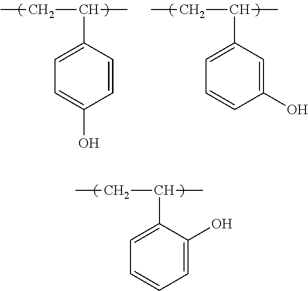

The content of the repeating unit represented by General Formula (III) in the polymer compound (A) is 3 mol % to 90 mol %, more preferably 5 mol % to 80 mol %, and still more preferably 7 mol % to 70 mol % in the case of a positive resist composition; and is preferably 60 mol % to 99 mol %, more preferably 70 mol % to 98 mol %, and still more preferably 75 mol % to 98 mol % in the case of a negative resist composition, based on the total repeating units in the polymer compound (A).

The polymer compound used in the present invention (A) also preferably further has a repeating unit as shown below.

For example, in the case of using the composition of the present invention as a positive resist composition, the polymer compound (A) preferably further includes a repeating unit having a group capable of decomposing by the action of an acid to generate an alkali-soluble group (hereinafter, which may be referred to as “repeating unit having an acid-decomposable group) other than the repeating unit having a structure in which a hydrogen atom of a phenolic hydroxyl group is substituted by a group represented by General Formula (I), or the repeating unit represented by General Formula (II) or (II′).

Examples of the alkali-soluble group include a phenolic hydroxyl group, a carboxyl group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group.

Preferred examples of the alkali-soluble group include a phenolic hydroxyl group, a carboxyl group, a fluorinated alcohol group (preferably hexafluoroisopropanol group), and a sulfonic acid group.

A preferred group as the acid-decomposable group is a group formed by substituting hydrogen atoms of these alkali-soluble groups with a group capable of leaving by the action of an acid.

Examples of the group capable of leaving by the action of an acid include —C(R₃₆)(R₃₇)(R₃₈), —C(R₃₆)(R₃₇)(OR₃₉), and —C(R₀₁)(R₀₂)(OR₃₉).

In the formulae, R₃₆ to R₃₉ each independently represent an alkyl group, a cycloalkyl group, a monovalent aromatic ring group, a group formed by combining an alkylene group and a monovalent aromatic ring group, or an alkenyl group. R₃₆ and R₃₇ may be bonded to each other to form a ring.

R₀₁ and R₀₂ each independently represent a hydrogen atom, an alkyl group, a cycloalkyl group, a monovalent aromatic ring group, a group formed by combining an alkylene group and a monovalent aromatic ring group, or an alkenyl group.

The repeating unit having an acid-decomposable group is preferably a repeating unit represented by the following General Formula (IV), since the repeating unit represented by the following General Formula (IV) exhibits high reactivity, low sensitivity variations in post-baking, and low process variations during manufacturing. The repeating unit represented by General Formula (IV) is a repeating unit having, in the side chain, an acetal group or ketal group capable of decomposing by the action of an acid to generate an alkali-soluble group, in a positive resist composition.

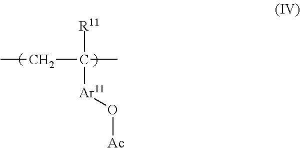

In General Formula (IV), R₁₁ represents a hydrogen atom or a methyl group. Ar₁₁ represents an arylene group. Ac is a group capable of leaving by the action of an acid, and —OAc represents an acetal group or ketal group capable of decomposing by the action of an acid to generate an alkali-soluble group.

A preferred aspect of the repeating unit represented by General Formula (IV) will be described.

R¹¹ in General Formula (IV) represents a hydrogen atom or a methyl group, and is particularly preferably a hydrogen atom.

Ar¹¹ in General Formula (IV) represents an arylene group, which may have a substituent. The arylene group of Ar¹¹ is preferably an arylene group having 6 to 18 carbon atoms, which may have a substituent group, more preferably a phenylene group or naphthylene group which may have a substituent, and most preferably a phenylene group which may have a substituent. Examples of the substituent which may be substituted on Ar¹¹ include an alkyl group, a halogen atom, a hydroxyl group, an alkoxy group, a carboxyl group, and an alkoxycarbonyl group.

In the repeating unit represented by General Formula (IV), when Ar¹¹ is a phenylene group, the bonding position of —OAc with respect to the benzene ring of Ar¹¹ may be a para-position, a meta-position, or an ortho-position with respect to the bonding position of the benzene ring to the polymer main chain, but is preferably a para-position or a meta-position.

Ac in General Formula (IV) is a group capable of leaving by the action of an acid, and —OAc represents an acetal group or ketal group capable of decomposing by the action of an acid to generate an alkali-soluble group. Specifically, Ac is preferably a group represented by the following General Formula (VI).

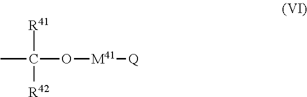

In General Formula (VI), R⁴¹ and R⁴² each independently represent a hydrogen atom, an alkyl group, a cycloalkyl group, an aryl group, or an aralkyl group.

M⁴¹ represents a single bond or a divalent linking group.

Q represents an alkyl group, an alicyclic group which may contain a heteroatom, or an aromatic ring group which may contain a heteroatom.

Further, at least two of R⁴¹, R⁴², M⁴¹, and Q may be bonded to each other to form a ring. This ring is preferably a 5- or 6-membered ring.

The alkyl group as R⁴¹ and R⁴² is, for example, an alkyl group having 1 to 8 carbon atoms. Preferred examples of the alkyl group include a methyl group, an ethyl group, a propyl group, an isopropyl group, an n-butyl group, a sec-butyl group, a tert-butyl group, a hexyl group, and an octyl group.

The cycloalkyl group as R⁴¹ and R⁴² is, for example, a cycloalkyl group having 3 to 15 carbon atoms. Preferred examples of the cycloalkyl group include a cyclohexyl group, a norbornyl group, and an adamantyl group.

The aryl group as R⁴¹ and R⁴² is, for example, an aryl group having 6 to 15 carbon atoms. Preferred examples of the aryl group include a phenyl group, a tolyl group, a naphthyl group, and an anthryl group.

The aralkyl group as R⁴¹ and R⁴² is, for example, an aralkyl group having 6 to 20 carbon atoms. Preferred examples of the aralkyl group include a benzyl group and a phenethyl group.

R⁴¹ and R⁴² are particularly preferably a hydrogen atom, a methyl group, a phenyl group, and a benzyl group. At least one of R⁴¹ or R⁴² is preferably a hydrogen atom (that is, —OAc is an acetal group capable of decomposing by the action of an acid to generate an alkali-soluble group).

The divalent linking group as M⁴¹ is, for example, an alkylene group (preferably an alkylene group having 1 to 8 carbon atoms, for example, a methylene group, an ethylene group, a propylene group, a butylene group, a hexylene group, or an octylene group), a cycloalkylene group (preferably a cycloalkylene group having 3 to 15 carbon atoms, for example, a cyclopentylene group or a cyclohexylene group), —S—, —O—, —CO—, —CS—, —SO₂—, —N(R₀)—, or a combination of two or more thereof, and a divalent linking group having a total of 20 or less carbon atoms is preferred. Here, R₀ is a hydrogen atom or an alkyl group (for example, an alkyl group having 1 to 8 carbon atoms, and specific examples thereof include a methyl group, an ethyl group, a propyl group, an n-butyl group, a sec-butyl group, a hexyl group, and an octyl group).

M⁴¹ is preferably a single bond, an alkylene group, or a divalent linking group composed of a combination of an alkylene group and at least one of —O—, —CO—, —CS—, or —N(R₀)—, and more preferably a single bond, an alkylene group, or a divalent linking group composed of a combination of an alkylene group and —O—. Here, R₀ has the same definition as R₀ above.

The alkyl group as Q is, for example, the same as the above-described alkyl group of R⁴¹ and R⁴².

The alicyclic group and aromatic ring group as Q include, for example, the above-described cycloalkyl group and aryl group of R⁴¹ and R⁴². The number of carbon atoms thereof is preferably 3 to 15. Incidentally, in the present invention, a group formed by combining plural aromatic rings through a single bond (for example, a biphenyl group and a terphenyl group) is also included in the aromatic group of Q.

Examples of the heteroatom-containing alicyclic group and heteroatom-containing aromatic ring group include thiirane, cyclothiolane, thiophene, furan, pyrrole, benzothiophene, benzofuran, benzopyrrole, triazine, imidazole, benzimidazole, triazole, thiadiazole, thiazole, and pyrrolidone. Incidentally, in the present invention, a group formed by combining plural “heteroatom-containing aromatic rings” through a single bond (for example, a viologen group) is also included in the aromatic group of Q.

The alicyclic group and aromatic ring group as Q may have a substituent, and examples thereof include an alkyl group, a cycloalkyl group, a cyano group, a halogen atom, a hydroxyl group, an alkoxy group, a carboxyl group, and an alkoxycarbonyl group.

(-M⁴¹-Q) is particularly preferably a methyl group, an aryloxyethyl group, a cyclohexylethyl group, or an arylethyl group.

Examples of the case where at least two members of R⁴¹, R⁴², M⁴¹, and Q are bonded to each other to form a ring include a case where either M⁴¹ or Q is bonded with R⁴¹ to form a propylene group or a butylene group and thereby form a 5- or 6-membered ring containing an oxygen atom.

With the total number of carbon atoms of R⁴¹, R⁴², M⁴¹, and Q being expressed as N_{C}, in the case where N_{C} has a large value, a change in an alkali dissolution rate of the polymer compound (A) before and after leaving of the group represented by General Formula (VI) is increased, and therefore the contrast of dissolution is preferably improved. The range of the value of N_{C} is preferably 4 to 30, more preferably 7 to 25, and particularly preferably 7 to 20. When the value of N_{C} is 30 or less, lowering of a glass transition temperature of the polymer compound (A) is prevented, and therefore the deterioration of exposure latitude (EL) of a resist film, or the remaining of residues resulting from leaving of a group represented by General Formula (VI) as a defect on the resist pattern are preferably inhibited.

In view of dry etching resistance, at least one of R⁴¹, R⁴², M⁴¹, or Q preferably has an alicyclic or aromatic ring. Here, the alicyclic group and the aromatic ring group are the same, for example, as the above-described alicyclic group and aromatic ring group of Q.

As the repeating unit capable of decomposing by the action of an acid to generate an alkali-soluble group, a repeating unit represented by General Formula (VII) is also preferred. In the actinic ray-sensitive or radiation-sensitive resin composition, the repeating unit represented by General Formula (VII) is a repeating unit capable of decomposing by the action of an acid to generate a carboxyl group as an alkali-soluble group in the side chain.

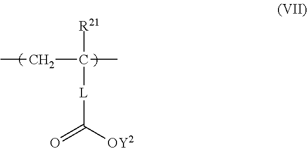

In General Formula (VII), R²¹ represents a hydrogen atom or a methyl group, L represents a single bond or a divalent linking group, and Y² represents a group capable of leaving by the action of an acid.

With respect to the repeating unit represented by General Formula (VII), preferred compounds for use in the present invention are described below.

In General Formula (VII), R²¹ represents a hydrogen atom or a methyl group and is particularly preferably a hydrogen atom.

In the case where L is a divalent linking group, examples thereof include an alkylene group, a cycloalkylene group, an arylene group, —O—, —SO₂—, —CO—, —N(R_{N})—, and a combination of plural these members. Here. R_{N} represents an aryl group, an alkyl group, or a cycloalkyl group.

The alkylene group as L is preferably an alkylene group having 1 to 10 carbon atoms, and examples thereof include a methylene group, an ethylene group, a propylene group, butylene group, a hexylene group, and an octylene group.

The cycloalkylene group as L is preferably a cycloalkylene group having 5 to 10 carbon atoms, and examples thereof include a cyclopentylene group and a cyclohexylene group.

The arylene group as L is preferably an arylene group having 4 to 20 carbon atoms, and examples thereof include a phenylene group and a naphthylene group.

The number of carbon atoms in the aryl group as R_{N} is preferably 4 to 20, and more preferably 6 to 14. Examples of the aryl group include a phenyl group and a naphthyl group.

The number of carbon atoms in the alkyl group as R_{N} is preferably 1 to 8. Examples of the alkyl group include a methyl group, an ethyl group, a propyl group, a butyl group, a hexyl group, and an octyl group.

The number of carbon atoms in the cycloalkyl group as R_{N} is preferably 5 to 8. Examples of the cycloalkyl group include a cyclopentyl group and a cyclohexyl group.

Each of the groups of L may further have a substituent, and specific examples of the substituent are the same as those of the substituent which may be further substituted on the arylene group of Ar¹¹.

Y² represents a group capable of leaving by the action of an acid and specifically, is preferably a group represented by the following formula.

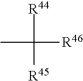

R₄₄ to R₄₆ each independently represent an alkyl group or a cycloalkyl group. Two of R⁴⁴ to R⁴⁶ may be bonded to each other to form a cycloalkyl group.

The alkyl group of R⁴⁴ to R⁴⁶ is preferably a linear or branched alkyl group having 1 to 4 carbon atoms.

The cycloalkyl group of R⁴⁴ to R⁴⁶ is preferably a monocyclic cycloalkyl group having 3 to 8 carbon atoms or a polycyclic cycloalkyl group having 7 to 20 carbon atoms.

The cycloalkyl group which may be formed by bonding two of R⁴⁴ to R₄₆ to each other is preferably a monocyclic cycloalkyl group having 3 to 8 carbon atoms or a polycyclic cycloalkyl group having 7 to 20 carbon atoms. Among them, particularly preferred is a monocyclic cycloalkyl group having 5 to 6 carbon atoms. More preferred is an aspect in which R⁴⁶ is a methyl group or an ethyl group, and R₄₄ and R⁴⁵ are bonded to form the above-mentioned cycloalkyl group.

Y² is also preferably a group represented by the following formula.

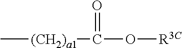

In the formula, R³⁰ represents a tertiary alkyl group having 4 to 20 carbon atoms, preferably 4 to 15 carbon atoms, a trialkylsilyl group in which each alkyl group has 1 to 6 carbon atoms, an oxoalkyl group having 4 to 20 carbon atoms, or a group represented by —C(R⁴⁴)(R⁴⁵)(R₄₆). Specific examples of the tertiary alkyl group include a tert-butyl group, a tert-amyl group, a 1,1-diethylpropyl group, a 1-ethylcyclopentyl group, a 1-butylcyclopentyl group, a 1-ethylcyclohexyl group, a 1-butylcyclohexyl group, a 1-ethyl-2-cyclopentenyl group, a 1-ethyl-2-cyclohexenyl group, and a 2-methyl-2-adamantyl group. Specific examples of the trialkylsilyl group include a trimethylsilyl group, a triethylsilyl group, and a dimethyl-tert-butylsilyl group. Specific examples of the oxoalkyl group include a 3-oxocyclohexyl group, a 4-methyl-2-oxooxan-4-yl group, and a 5-methyl-2-oxooxolan-5-yl group. a1 is an integer of 1 to 6.

Specific examples of the repeating unit having a group capable of decomposing by the action of an acid to generate an alkali-soluble group are illustrated below, but the present invention is not limited thereto.

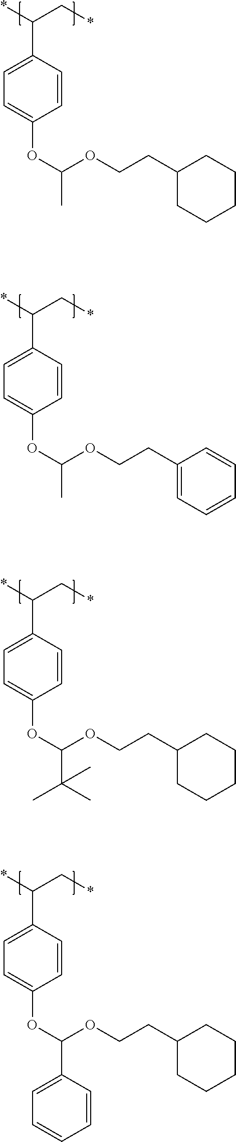

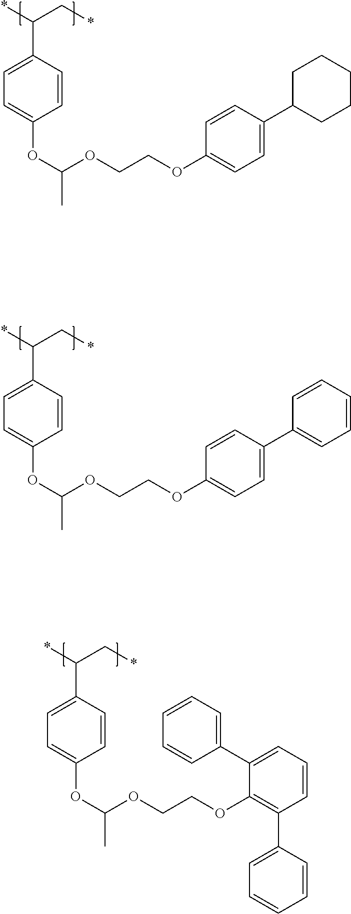

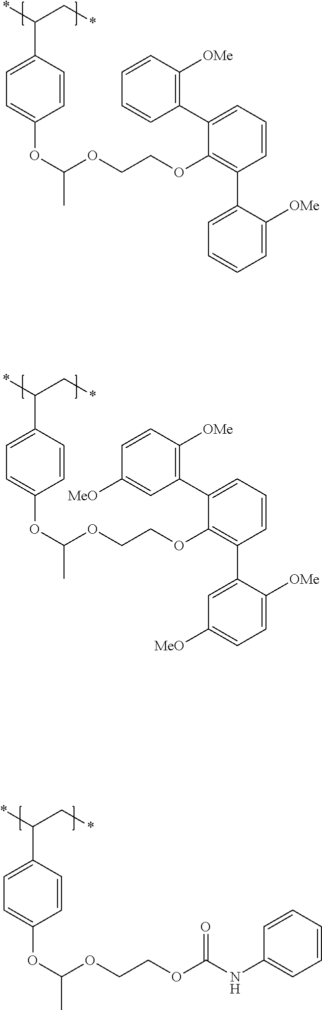

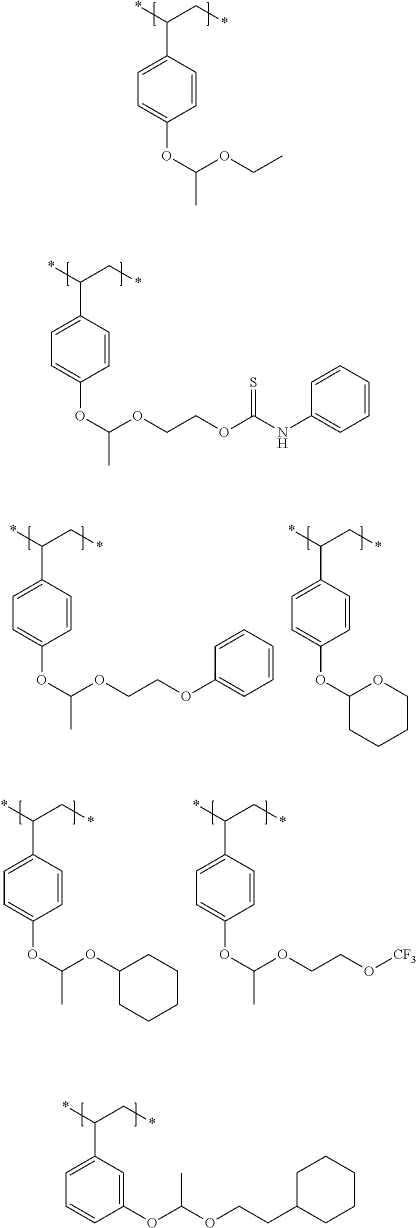

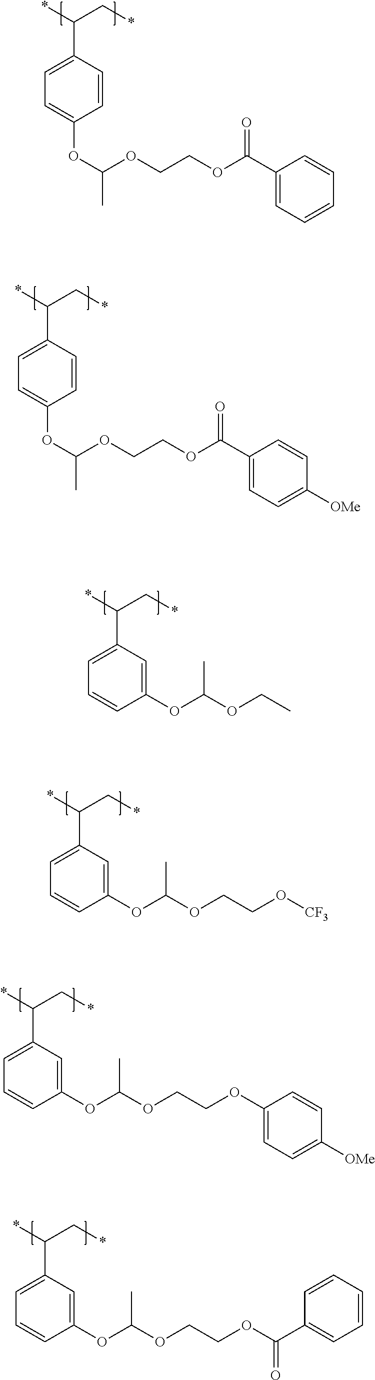

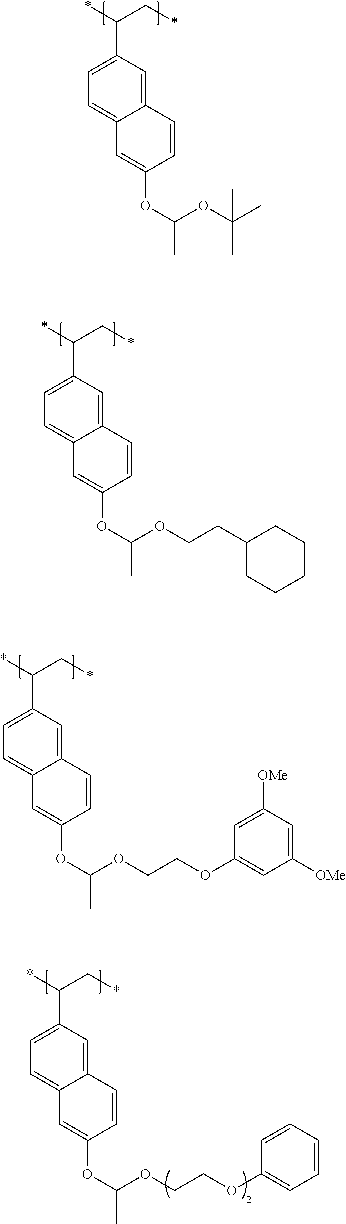

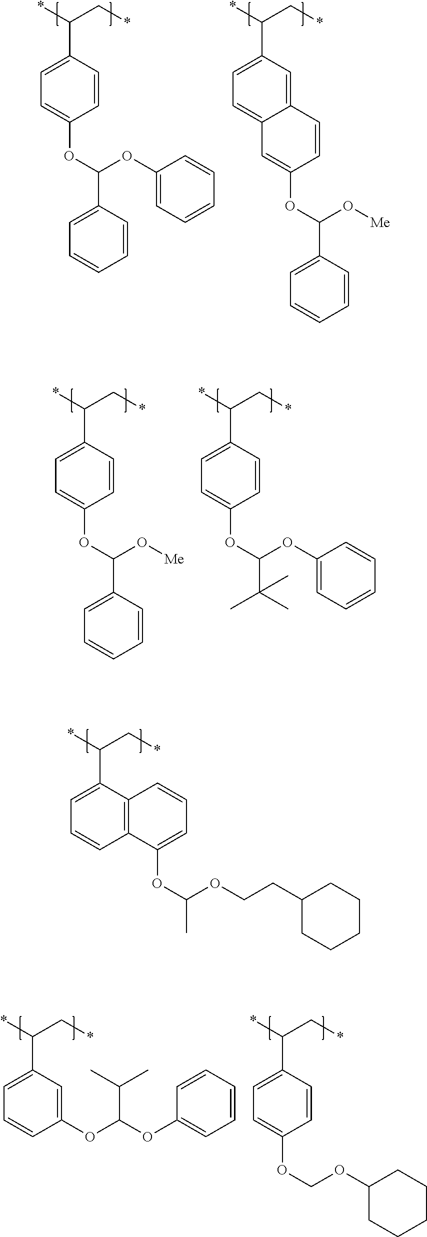

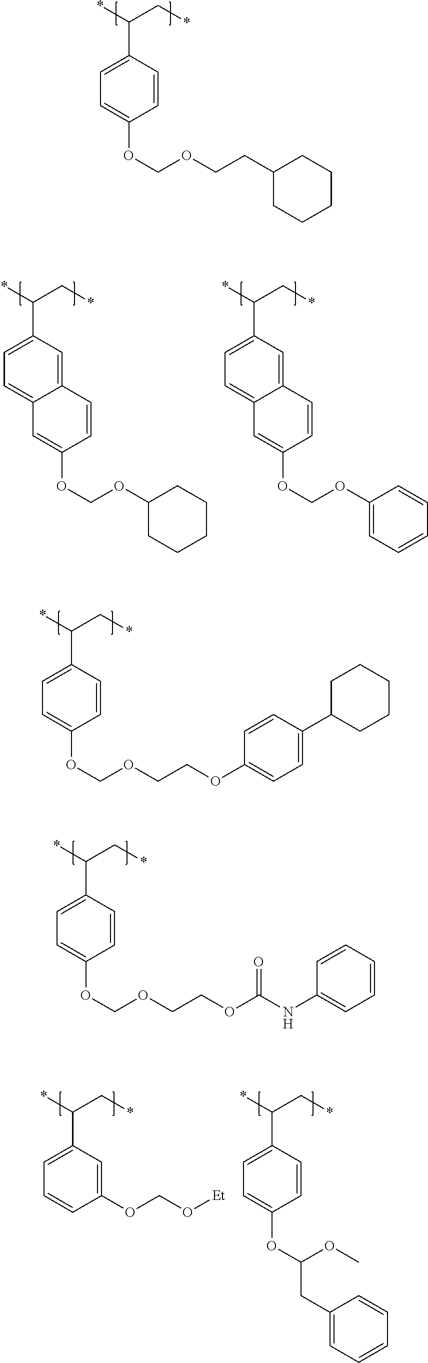

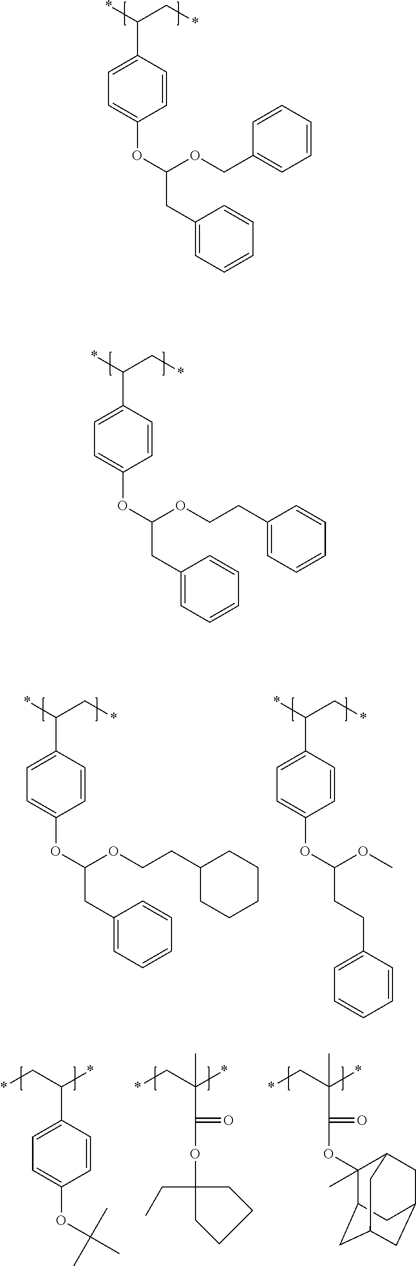

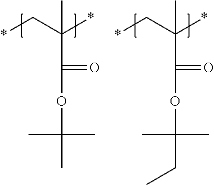

In the polymer compound (A) in the case of using the composition of the present invention as a positive resist composition, the content of the repeating unit capable of decomposing by the action of an acid to generate an alkali-soluble group, other than the repeating unit having a structure in which a hydrogen atom of a phenolic hydroxyl group is substituted by a group represented by General Formula (I), or the repeating unit represented by General Formula (II) or (II′), is preferably in the range of 3 mol % to 90 mol %, more preferably 5 mol % to 80 mol %, and still more preferably 7 mol % to 70 mol %, based on the total repeating units in the polymer compound (A).

It is also preferred that the polymer compound (A) for use in the present invention further contains the following repeating unit as a repeating unit other than the above-described repeating units.

For example, in the case of using the composition of the present invention as a positive resist composition, the polymer compound (A) may further contain a repeating unit having a group capable of decomposing by the action of an alkali developer to increase the dissolution rate in an alkali developer. Examples of such a group include a group having a lactone structure, and a group having a phenyl ester structure. The repeating unit having a group capable of decomposing by the action of an alkali developer to increase the dissolution rate in an alkali developer is more preferably a repeating unit represented by the following General Formula (AII).

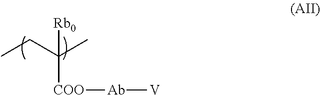

In General Formula (AII), V represents a group capable of decomposing by the action of an alkali developer to increase the dissolution rate in an alkali developer, Rb₀ represents a hydrogen atom or a methyl group, and Ab represents a single bond or a divalent organic group.

V as a group capable of decomposing by the action of an alkali developer is a group having an ester bond and preferably a group having a lactone structure. As for the group having a lactone structure, any group may be used as long as it has a lactone structure, but the group is preferably a 5- to 7-membered ring lactone structure, and a 5- to 7-membered ring lactone structure to which another ring structure is fused to form a bicyclo structure or a spiro structure is more preferred.

Ab is preferably a single bond or a divalent linking group represented by -AZ—CO₂— (in which AZ is an alkylene group or an aliphatic ring group). AZ is preferably a methylene group, an ethylene group, a cyclohexylene group, an adamantylene group, or a norbornylene group.

Specific examples are illustrated below. In the formulae, Rx represents H or CH₃.

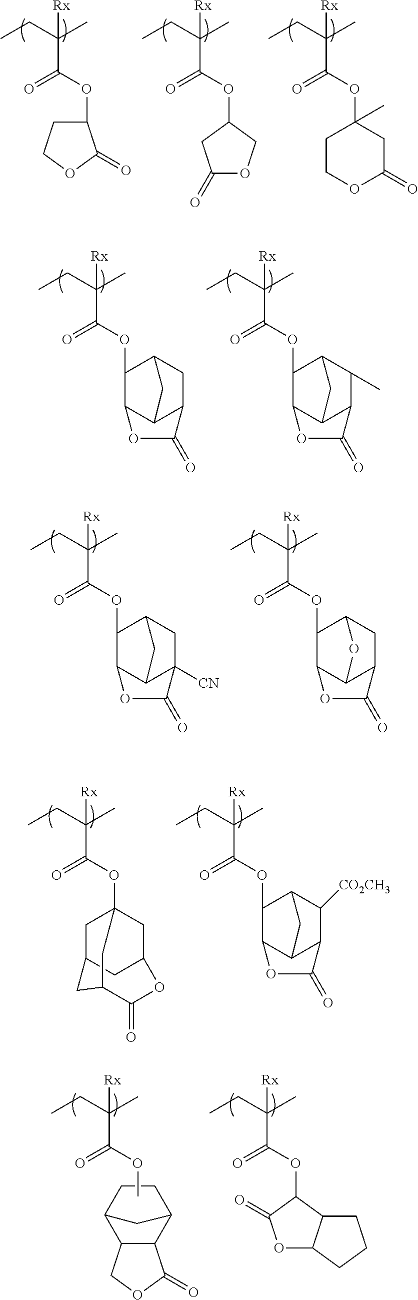

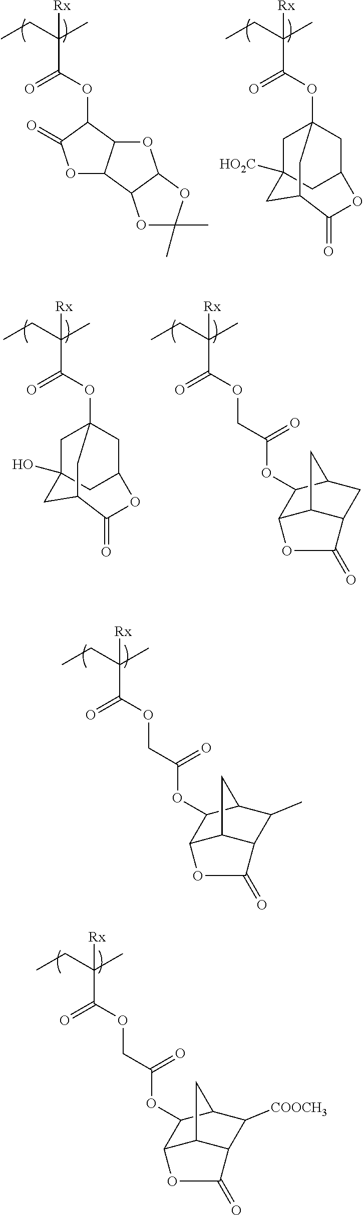

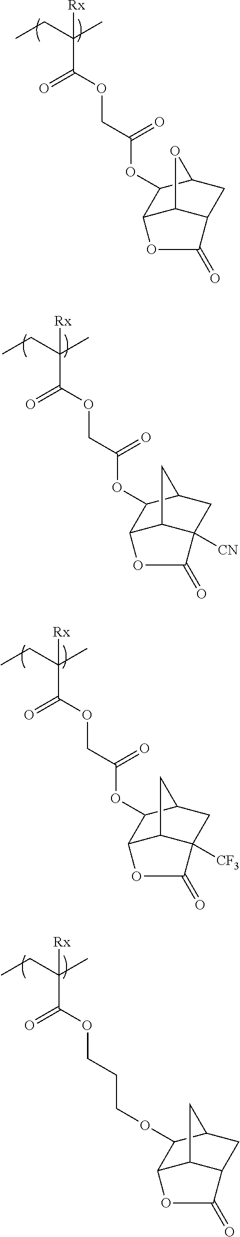

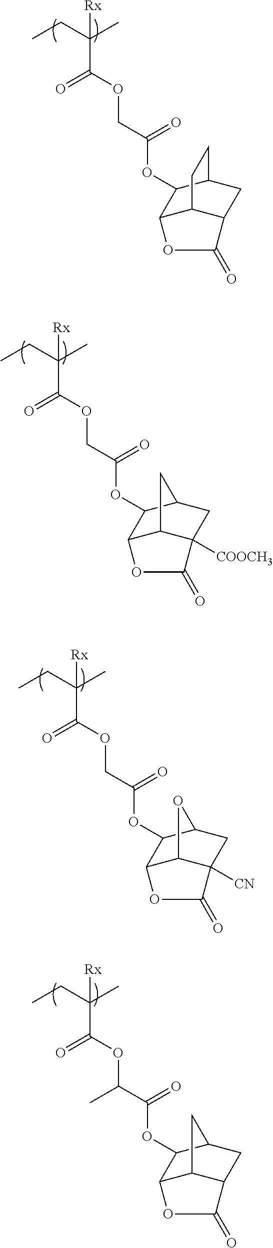

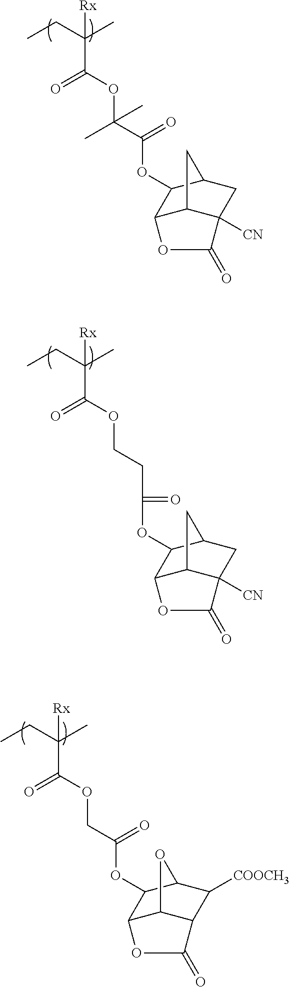

The polymer compound (A) in the case of using the composition of the present invention as a positive resist composition may or may not contain a repeating unit having a group capable of decomposing by the action of an alkali developer to increase the dissolution rate in an alkali developer, but in the case of containing the repeating unit having the group above, the content thereof is preferably 5 mol % to 60 mol %, more preferably 10 mol % to 50 mol %, and still more preferably 10 mol % to 40 mol %, based on the total repeating units in the polymer compound (A).

The polymer compound (A) for use in the present invention preferably further contains a repeating unit having, in the side chain, a group capable of generating an acid upon irradiation with actinic rays or radiation (hereinafter, sometimes referred to as a “photoacid generating group”). In this case, the compound (B) capable of generating an acid upon irradiation with actinic rays or radiation, which is an essential component of the present invention, is not an independent compound but becomes one constituent component in the polymer compound (A) according to the present invention. That is, in one preferred aspect of the present invention, the polymer compound (A) further contains a repeating unit having, in the side chain, a group capable of generating an acid upon irradiation with actinic rays or radiation, and the polymer compound (A) and the compound (B) are an identical compound.

An example of the repeating unit having a photoacid generating group in the side chain includes a repeating unit represented by the following General Formula (VIII).

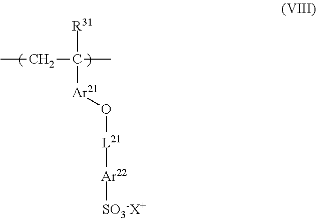

In General Formula (VIII). R³¹ represents a hydrogen atom or a methyl group, Ar²¹ represents an arylene group. L²¹ represents a divalent organic group, Ar²² represents an arylene group, and X⁺ represents an onium cation.

R³¹ in General Formula (VIII) represents a hydrogen atom or a methyl group and is preferably a hydrogen atom. Ar²¹ represents an arylene group, which may have a substituent. Ar²¹ is preferably a phenylene group. L²¹ represents a divalent organic group, preferably a carbonyl group, —CH₂COO—, —CO—CH₂—O—, —CO—CH₂—O—CO—, —CH₂—CONR¹—, or —CO—CH₂—NR₁—, and more preferably a carbonyl group or —CH₂COO—. R₁ represents a hydrogen atom, an alkyl group (preferably having 1 to 8 carbon atoms), an aryl group (preferably having 6 to 15 carbon atoms), or an aralkyl group (preferably having 6 to 20 carbon atoms). Ar²² represents an arylene group, which may have a substituent. Ar²¹ may have a substituent and is preferably a phenylene group or a naphthylene group, and particularly preferably a substituted phenylene group. X⁺ represents an onium cation and is preferably a sulfonium cation or an iodonium cation, and particularly preferably an aryl sulfonium cation or an aryl iodonium cation.

Examples of the substituent which may be substituted on Ar²¹ and Ar²² include the same substituents as in specific examples and preferred ranges of the substituent which may be substituted on R₁ in General Formula (I).

Specific examples of such a repeating unit having a photoacid generating group in the side chain include repeating units shown below.

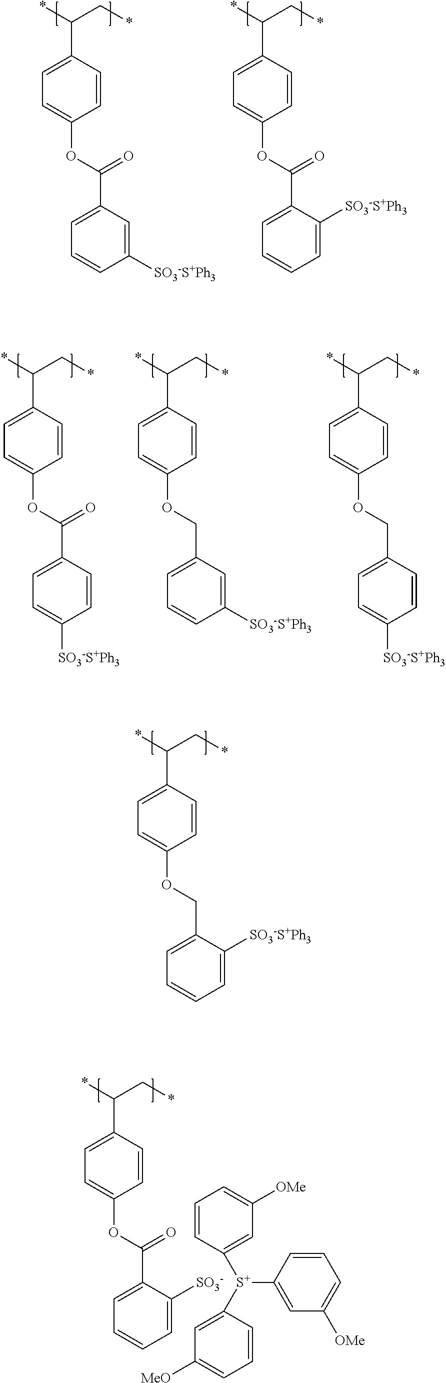

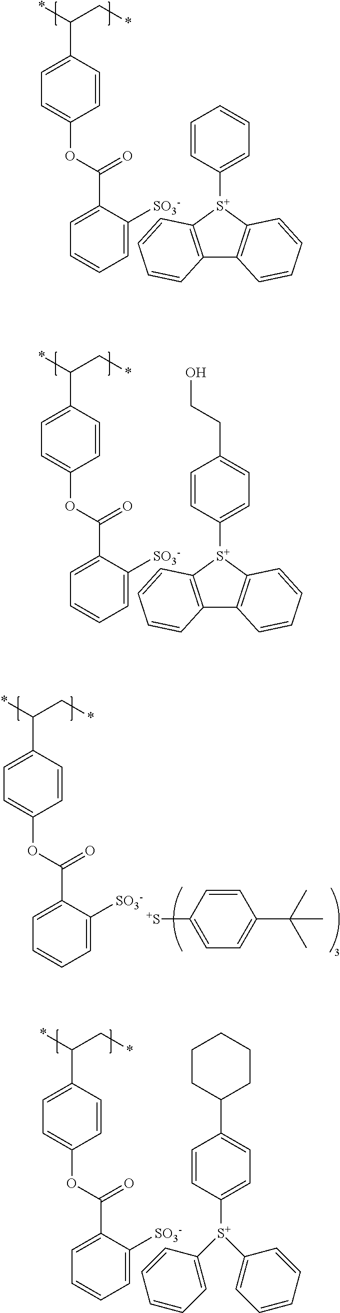

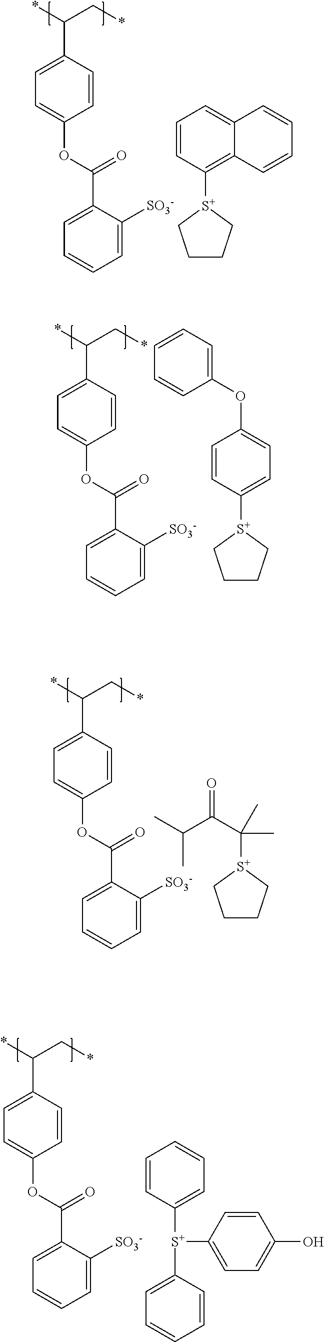

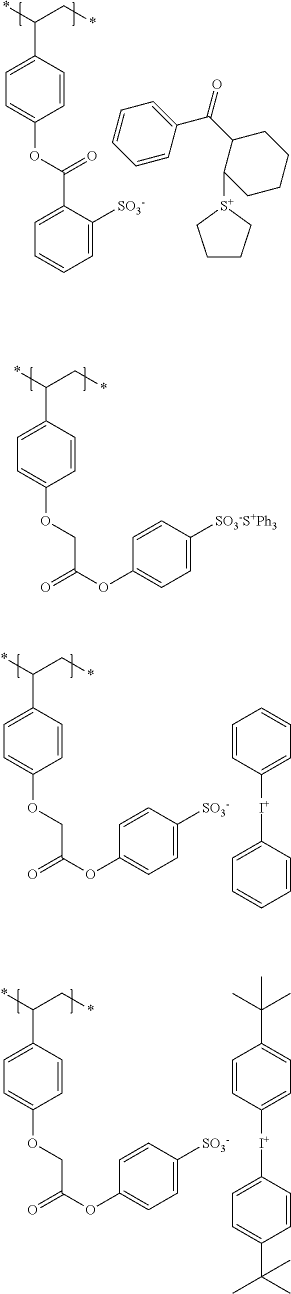

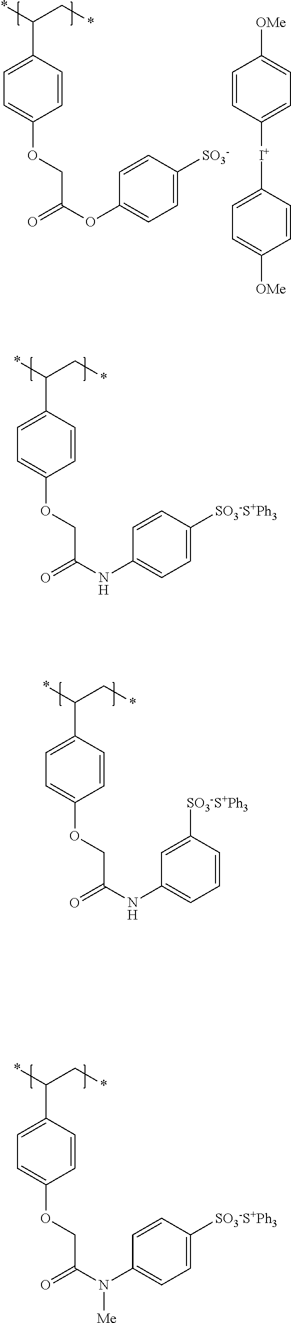

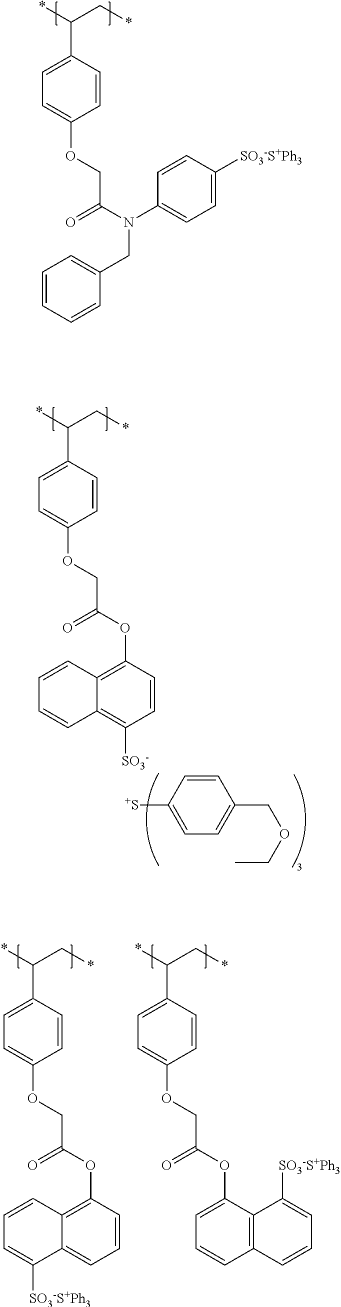

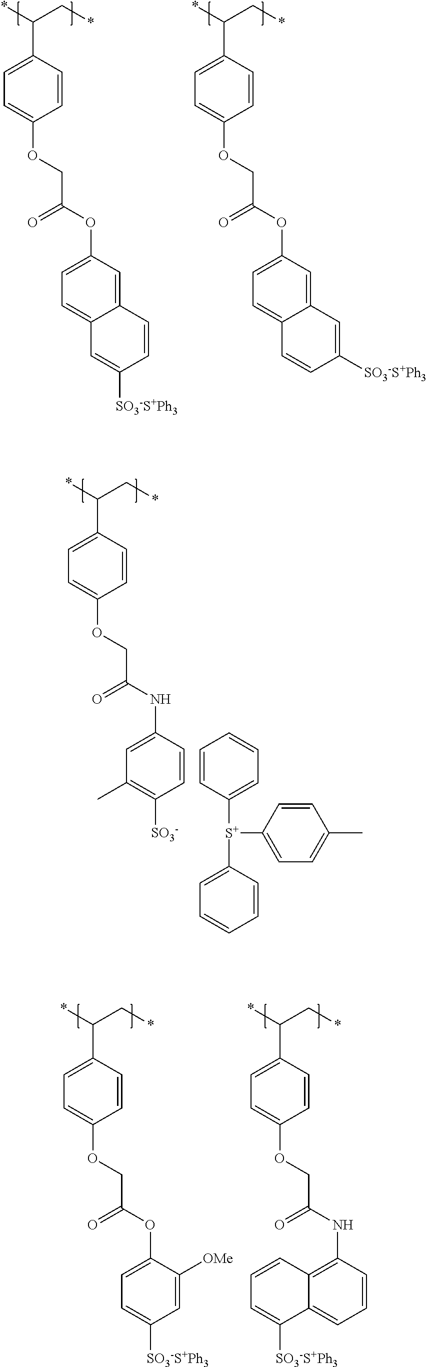

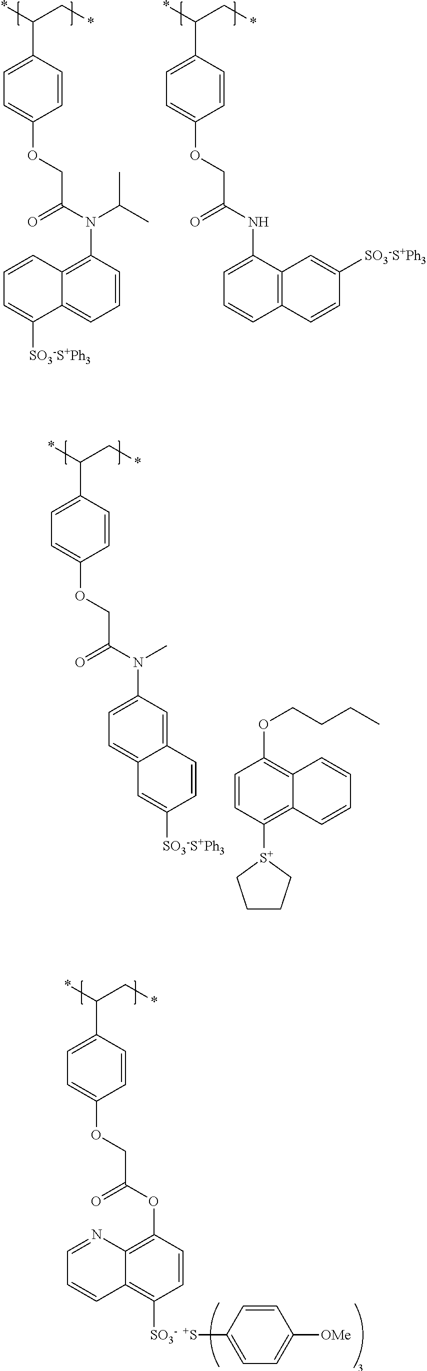

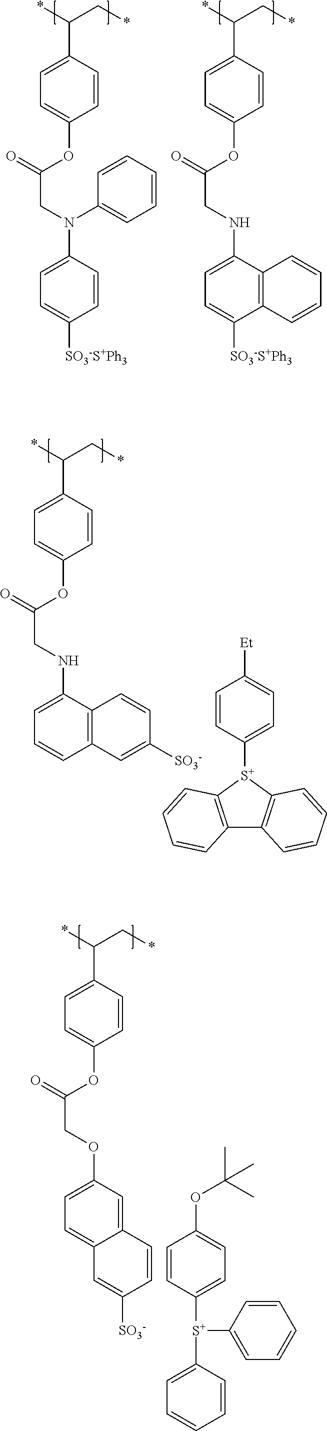

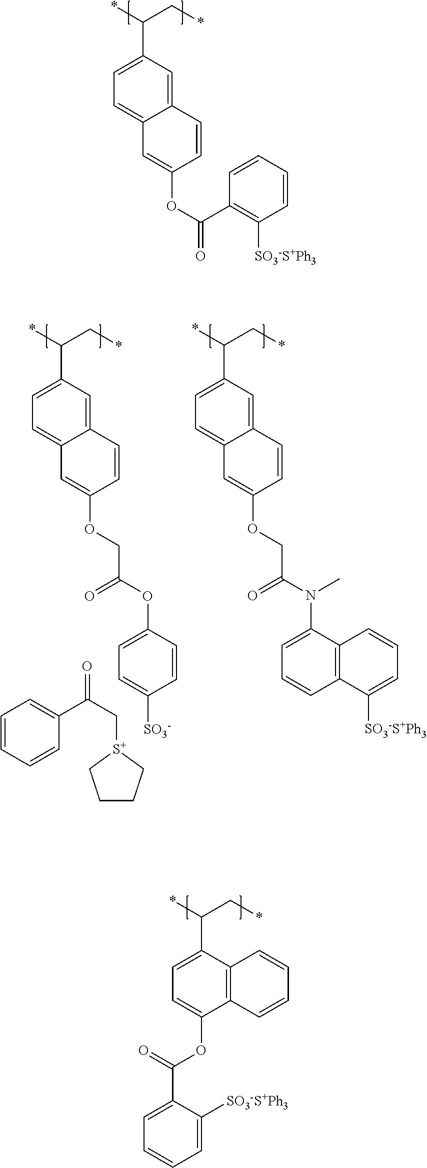

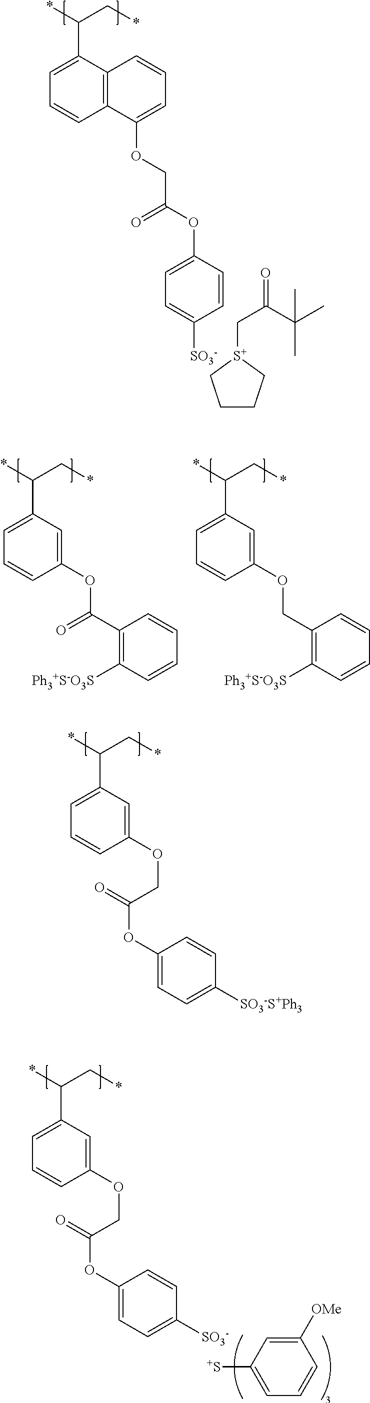

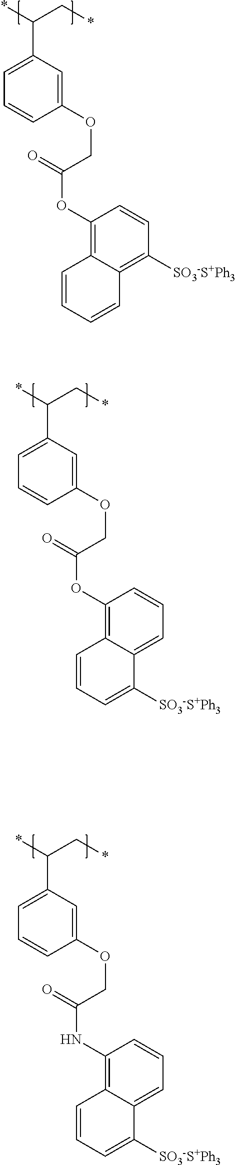

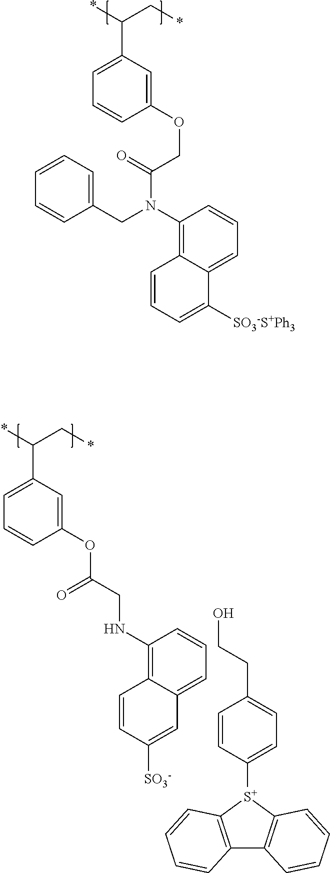

Examples of the polymerizable monomer for forming a repeating unit other than those described above in the polymer compound (A) include styrene, alkyl-substituted styrene, alkoxy-substituted styrene, O-alkylated styrene, O-acylated styrene, hydrogenated hydroxystyrene, a maleic anhydride, an acrylic acid derivative (for example, acrylic acid, acrylic acid ester), a methacrylic acid derivative (for example, methacrylic acid, methacrylic acid ester), an N-substituted maleimide, acrylonitrile, methacrylonitrile, vinylnaphthalene, vinylanthracene, indene which may have a substituent, and a polymerizable monomer having an alcoholic hydroxyl group substituted with a fluoroalkyl group or the like at the α-position. Preferred examples of the substituted styrene include 4-(1-naphthylmethoxy)styrene, 4-benzyloxystyrene, 4-(4-chlorobenzyloxy)styrene, 3-(1-naphthylmethoxy)styrene, 3-benzyloxy styrene, and 3-(4-chlorobenzyloxy)styrene.

The polymer compound (A) may or may not contain such other repeating unit, but in the case of containing such other repeating unit, the content thereof in the polymer compound (A) is generally 1 mol % to 20 mol %, and preferably 2 mol % to 10 mol %, based on the total repeating units constituting the polymer compound (A).

The polymer compound (A) can be synthesized, for example, by radical, cationic or anionic polymerization of unsaturated monomers corresponding to respective repeating units. The polymer compound can be also synthesized by polymerizing a polymer from unsaturated monomers corresponding to precursors of respective repeating units, and modifying the synthesized polymer with a low molecular compound, thereby converting the precursors into desired repeating units, in either case, living polymerization such as living anionic polymerization is preferably used, because the obtained polymer compound can have a uniform molecular weight distribution.

The weight average molecular weight of the polymer compound (A) is preferably 1,000 to 200,000, more preferably 2,000 to 50,000, and still more preferably 2,000 to 15.000. The polydispersity (molecular weight distribution) (Mw/Mn) of the polymer compound (A) is, in view of sensitivity, preferably from 1.0 to 1.7, and more preferably from 1.0 to 1.2. The weight average molecular weight and the polydispersity of the polymer compound (A) are defined in terms of polystyrene by GPC measurement.

In the present specification, the weight average molecular weight and polydispersity can be determined, for example using HLC-8120 (manufactured by Tosoh Corporation), TSK gel Multipore HXL-M (manufactured by Tosoh Corporation, 7.8 mmID×30.0 cm) as a column, and tetrahydrofuran (THF) as an eluting solution.

In the composition of the present invention, two or more of these polymer compounds (A) may be mixed and used.

The content of the polymer compound (A) is preferably 30 mass % to 100 mass %, more preferably 50 mass % to 99.7 mass %, and particularly preferably 70 mass % to 99.5 mass %, based on the total solid content of the composition of the present invention.

[2] (B) Compound Capable of Generating Acid Upon Irradiation with Actinic Rays or Radiation

The actinic ray-sensitive or radiation-sensitive resin composition of the present invention further contains (B) a compound capable of generating an acid upon irradiation with actinic rays or radiation (hereinafter, sometimes simply referred to as an “acid generator”) as an essential component. In the present invention, the compound (B) capable of generating an acid upon irradiation with actinic rays or radiation may be a low-molecular weight acid generator capable of generation an acid upon irradiation with actinic rays or radiation (particularly an electron beam or extreme ultraviolet rays) or may be an acid-generating polymer compound. As described above, also preferred is an embodiment in which the compound (B) is integrated as one constituent component of the polymer compound (A), that is, the polymer compound (A) includes a repeating unit further containing a group capable of generating an acid upon irradiation with actinic rays or radiation in the main chain or side chain.

A preferred aspect of the acid generator is an onium compound. Examples of the onium compound include a sulfonium salt, an iodonium salt, and a phosphonium salt.

Another preferred embodiment of the acid generator is a compound capable of generating a sulfonic acid, an imide acid, or a methide acid upon irradiation with actinic rays or radiation. Examples of the acid generator in this embodiment include a sulfonium salt, an iodonium salt, a phosphonium salt, oxime sulfonate, and imidosulfonate.

The acid generator for use in the present invention is not limited to a low-molecular weight compound, and a compound where a group capable of generating an acid upon irradiation with actinic rays or radiation is introduced into the main or side chain of a polymer compound may also be used. Furthermore, in the case where, as described above, a group capable of generating an acid upon irradiation with actinic rays or radiation is present in a repeating unit serving as a copolymerization component of the polymer compound (A) for use in the present invention, the acid generator (B) as a molecule different from the polymer compound (A) of the present invention may be absent.

The acid generator is preferably a compound capable of generating an acid upon irradiation with an electron beam or extreme ultraviolet rays.

In the present invention, the onium compound is preferably a sulfonium compound represented by the following General Formula (I) or an iodonium compound represented by General Formula (2).

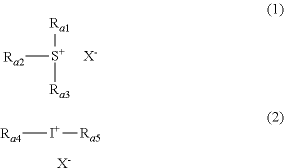

In General Formulae (1) and (2),

Rₐ₁, Rₐ₂, Rₐ₃, Rₐ₄, and Rₐ₅ each independently represent an organic group.

X⁻ represents an organic anion.

Hereinafter, the sulfonium compound represented by General Formula (1) and the iodonium compound represented by General Formula (2) will be described in more detail.

Rₐ₁ to Rₐ₃ in General Formula (1) and Rₐ₄ and Rₐ₅ in General Formula (2) each independently represent an organic group, but each of at least one of Rₐ₁, Rₐ₂, or Rₐ₃ and at least one of Rₐ₄ or Rₐ₅ is preferably an aryl group. The aryl group is preferably a phenyl group or a naphthyl group, and more preferably a phenyl group.

Examples of the organic anion of X⁻ in General Formulae (1) and (2) include a sulfonate anion, a carboxylate anion, a bis(alkylsulfonyl)amide anion, and a tris(alkylsulfonyl)methide anion. The organic anion is preferably an organic anion represented by the following General Formula (3), (4), or (5), and more preferably an organic anion represented by the following General Formula (3).

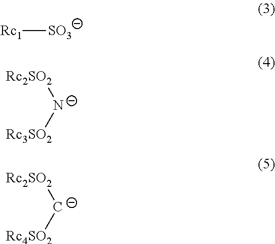

In General Formulae (3), (4), and (5), each of Rc₁, Rc₂, Rc₃, and Rc₄ represents an organic group.

The organic anion of X⁻ corresponds to a sulfonic acid, an imide acid, or a methide acid which is an acid generated upon irradiation with actinic rays or radiation such as an electron beam and extreme ultraviolet rays.

Examples of the organic group of R_{c1} to R_{c4} include an alkyl group, an aryl group, and a group formed by combining a plurality of such groups. Among these organic groups, preferred are an alkyl group substituted with a fluorine atom or a fluoroalkyl group at the 1-position, and a phenyl group substituted with a fluorine atom or a fluoroalkyl group. By having a fluorine atom or a fluoroalkyl group, the acidity of the acid generated by light irradiation is increased and the sensitivity is enhanced. However, the terminal group preferably contains no fluorine atom as a substituent.

Also, in the present invention, in view of suppressing diffusion of an acid generated by exposure into a non-exposed area, thereby improving a resolution or a pattern profile, the compound (B) which generates an acid is preferably a compound which generates an acid with a volume of 130 Å³ or more (more preferably, a sulfonic acid), more preferably a compound which generates an acid with a volume of 190 Å³ or more (more preferably, a sulfonic acid), still more preferably a compound which generates an acid with a volume of 270 Å³ or more (more preferably, a sulfonic acid), and particularly preferably a compound which generates an acid with a volume of 400 Å³ or more (more preferably, a sulfonic acid). Meanwhile, in view of the sensitivity or the coating solvent solubility, the volume is preferably 2000 Å³ or less, and more preferably 1500 Å³ or less. The value of the volume was obtained using, “WinMOPAC” manufactured by FUJITSU LIMITED. That is, the “accessible volume” of each acid may be calculated by, first, inputting a chemical structure of an acid according to each case, determining the most stable conformation of each acid by a molecular force field calculation using a MM3 method with an initial structure of this structure, and then performing a molecular orbital calculation using a PM3 method for the most stable conformation.

A particularly preferred acid generator in the present invention will be exemplified as below. Also, some examples are given calculated values of volume (unit: Å³). Meanwhile, the value calculated herein is a volume value of an acid in which a proton is bound to an anion moiety.

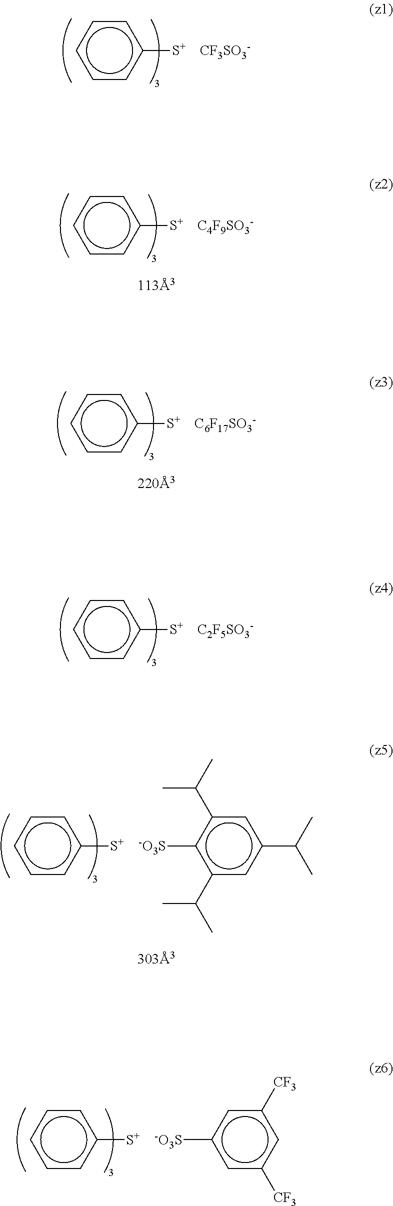

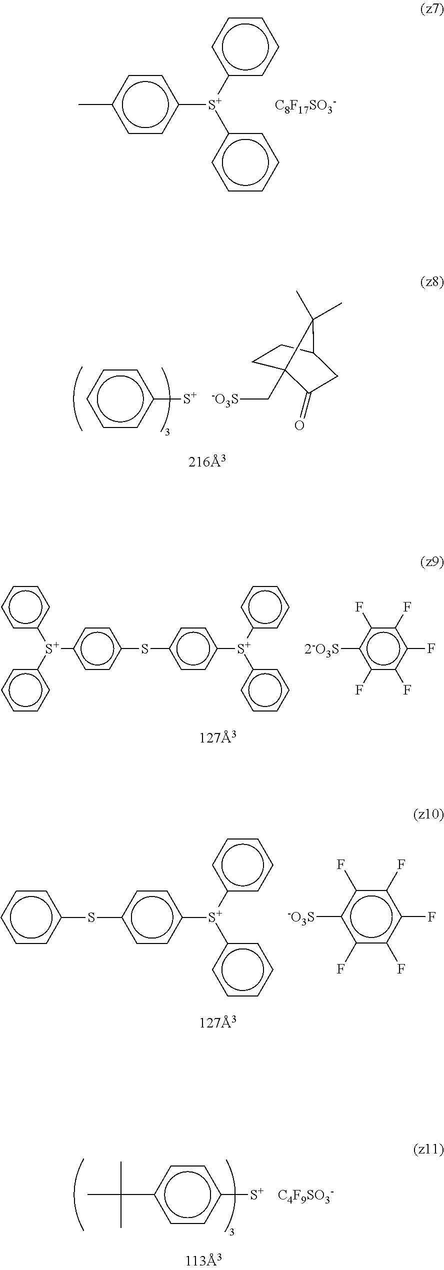

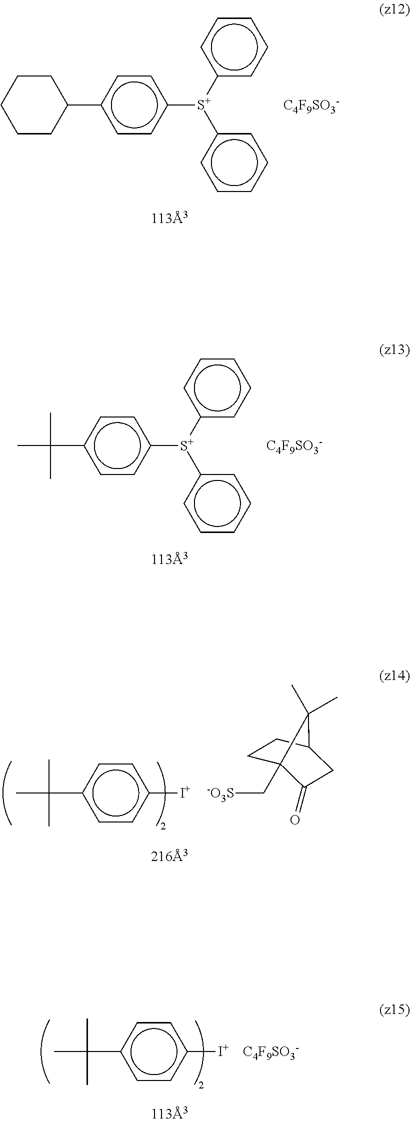

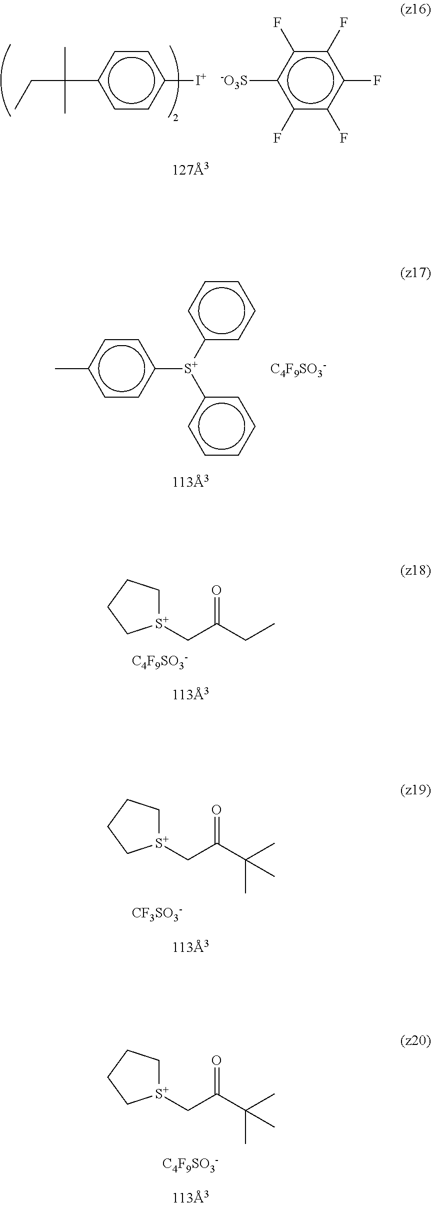

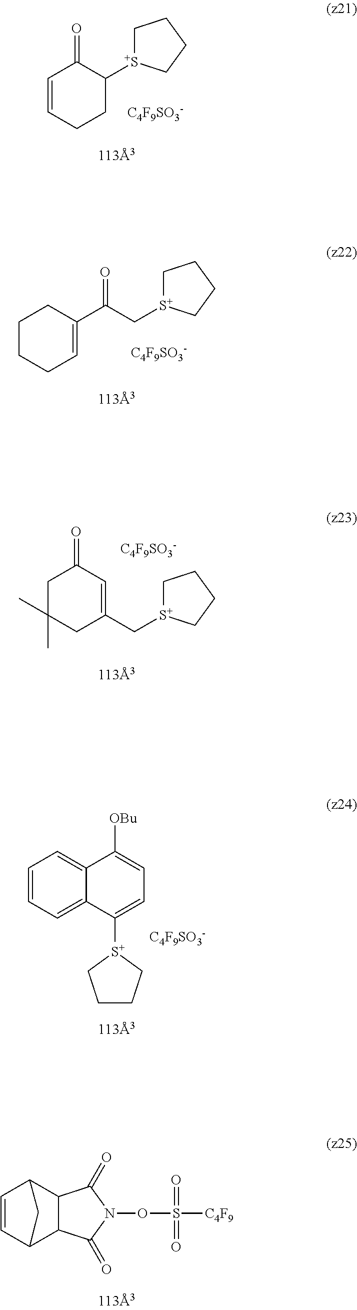

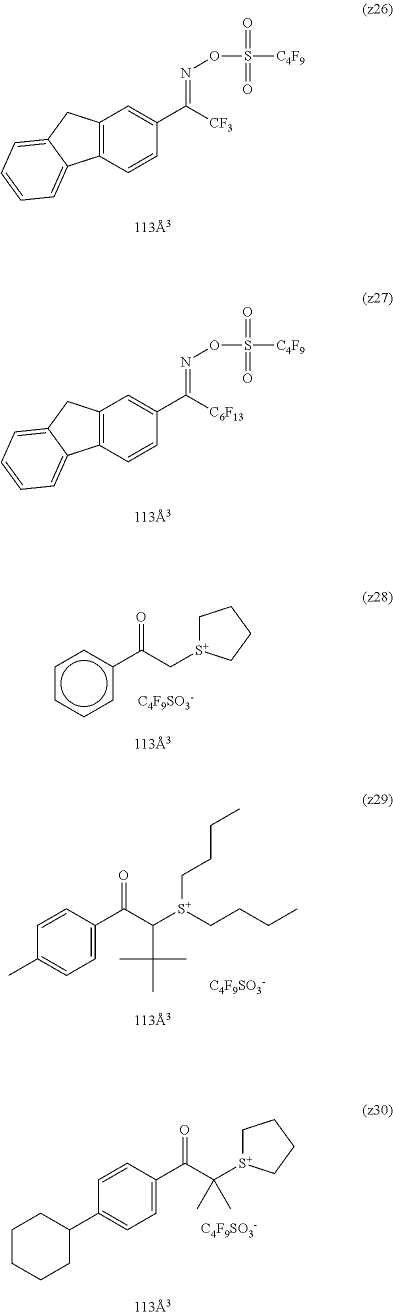

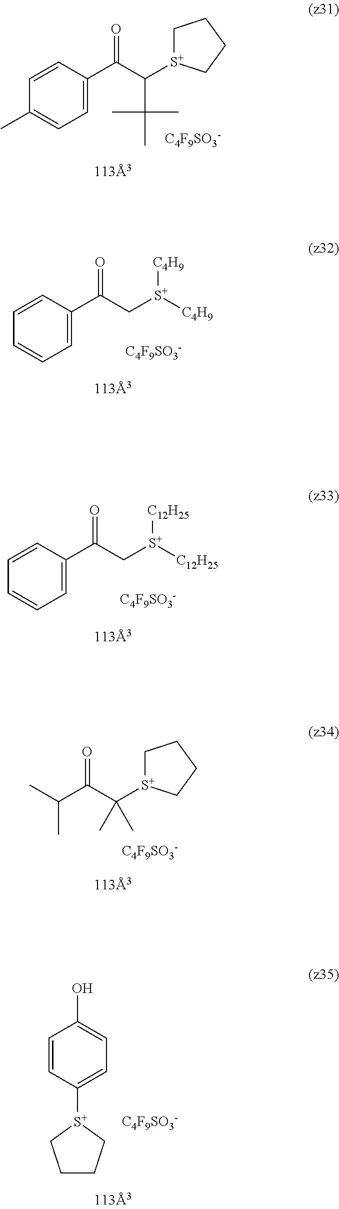

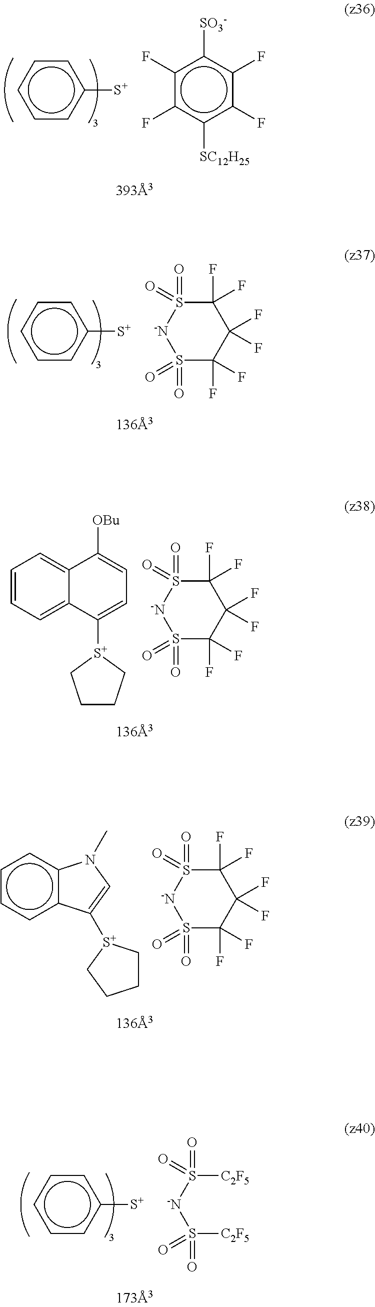

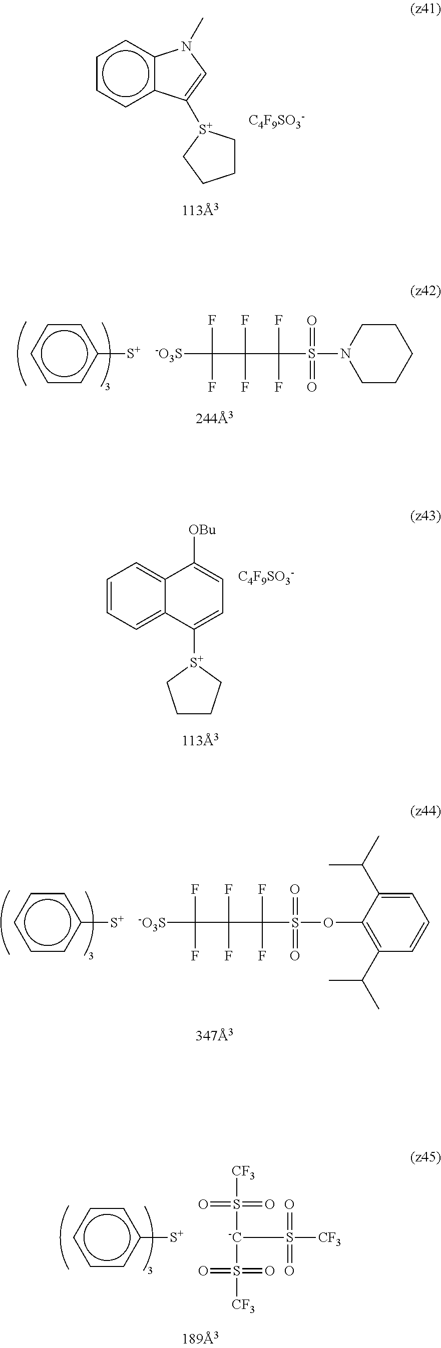

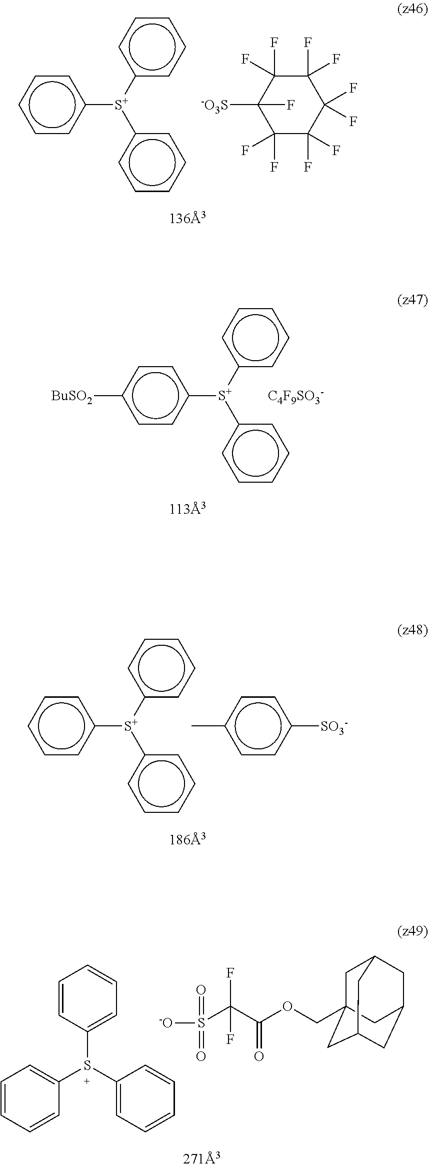

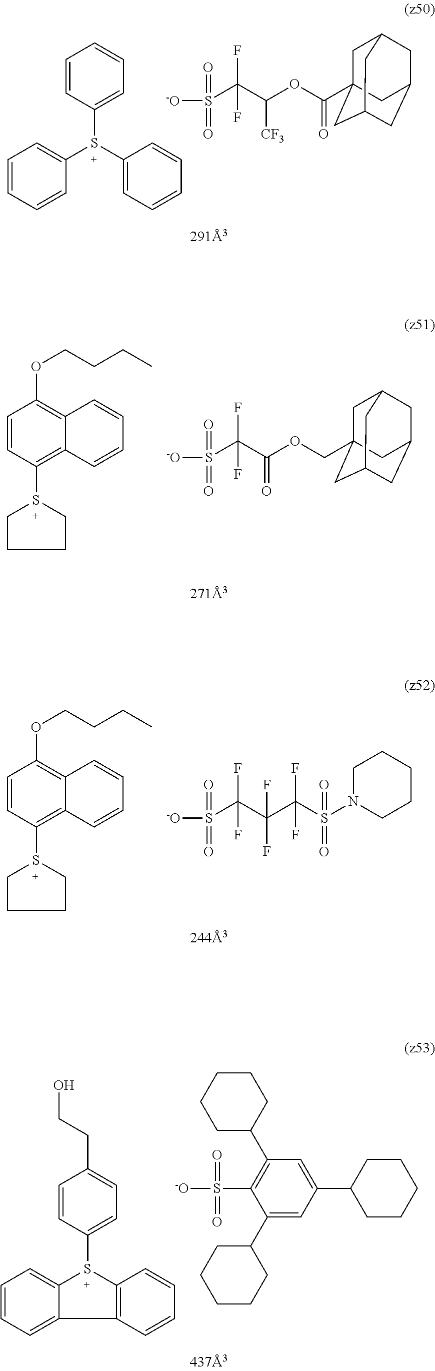

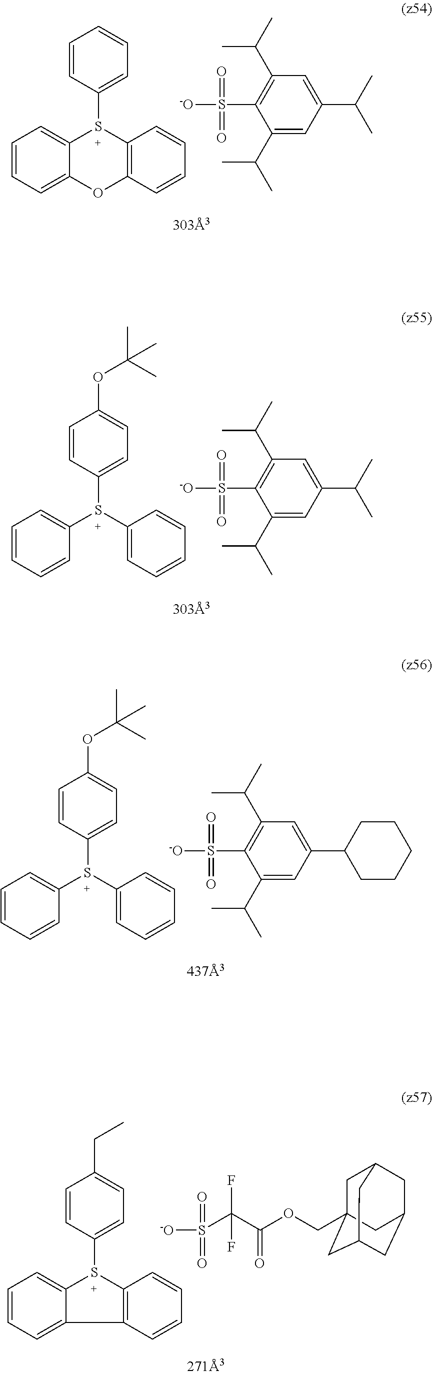

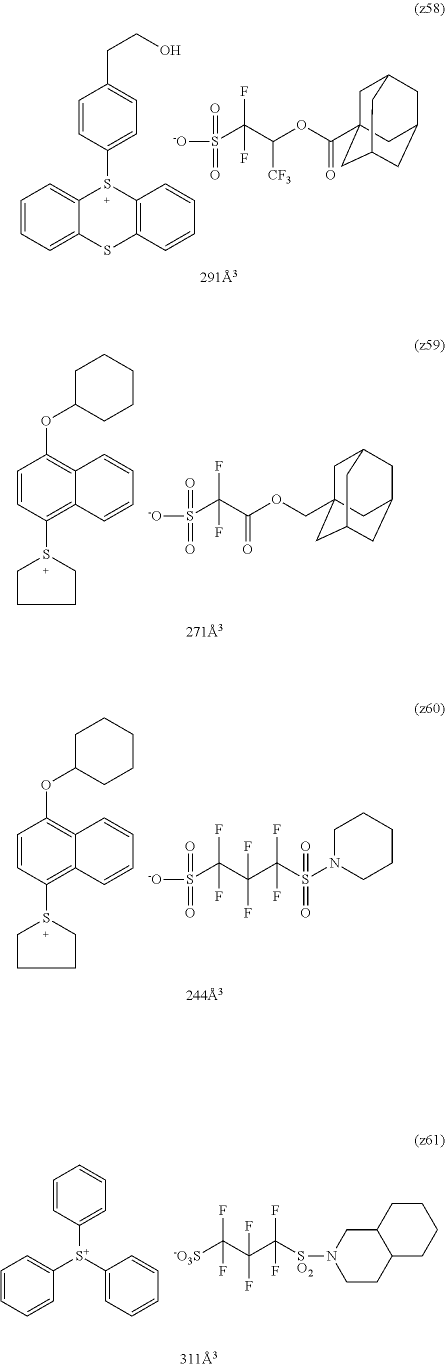

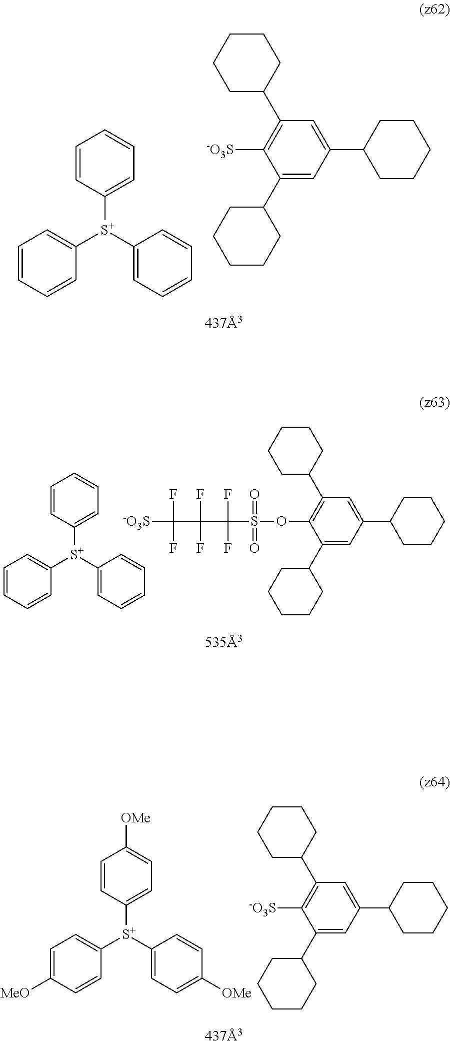

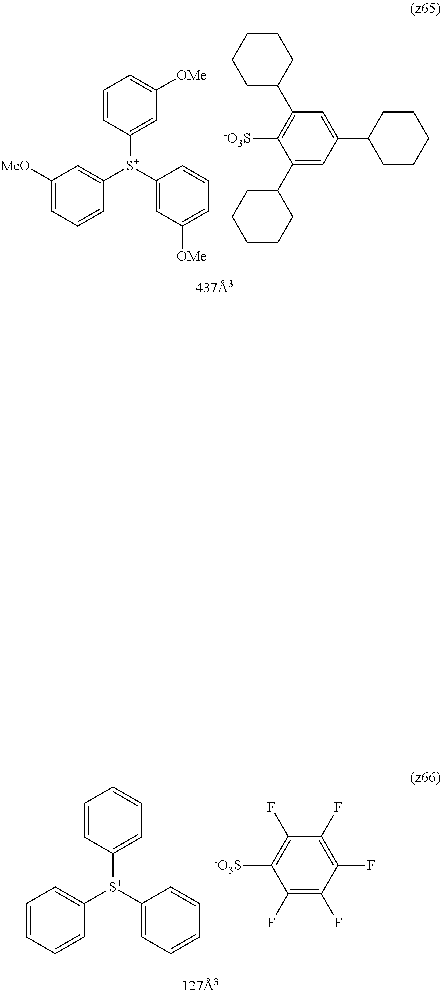

As the acid generator (preferably an onium compound) for use in the present invention, a compound where a group capable of generating an acid upon irradiation with actinic rays or radiation (photoacid generating group) is introduced into the main or side chain of a polymer compound may also be used, and this acid generator is described as a repeating unit having a photoacid generating group in connection with the polymer compound (A).

The content of the acid generator in the composition of the present invention is preferably 0.1 mass % to 25 mass %, more preferably 0.5 mass % to 20 mass %, and still more preferably 1 mass % to 18 mass %, based on the total solid content of the composition.

The acid generator may be used alone or in combination of two or more thereof.

[3] Compound having Two or More Hydroxymethyl Groups or Alkoxymethyl Groups in Molecule

In the case of using the composition of the present invention as a negative chemically amplified resist composition, the composition of the present invention preferably contains (C) a compound having two or more hydroxymethyl groups or alkoxymethyl groups in the molecule (hereinafter, appropriately referred to as “acid crosslinking agent” or simply referred to as “crosslinking agent”) as a crosslinking agent.

Examples of the preferred crosslinking agent include hydroxymethylated or alkoxymethylated phenol compounds, alkoxymethylated melamine-based compounds, alkoxymethyl glycoluril-based compounds, and alkoxymethylated urea-based compounds. Examples of the compound (C) as the particularly preferred crosslinking agent include a phenol derivative having a molecular weight of 1.200 or less and containing, within the molecule, three to five benzene rings and a total of two or more hydroxymethyl groups or alkoxymethyl groups, a melamine-formaldehyde derivative having at least two free N-alkoxymethyl groups, and an alkoxymethyl glycoluril derivative.

The alkoxymethyl group is preferably a methoxymethyl group or an ethoxymethyl group.

Among the crosslinking agents, a phenol derivative having a hydroxymethyl group may be obtained by reacting a corresponding phenol compound having no hydroxymethyl group with formaldehyde in the presence of a base catalyst. Also, a phenol derivative having an alkoxymethyl group may be obtained by reacting a corresponding phenol derivative having a hydroxymethyl group with an alcohol in the presence of an acid catalyst.

Among the phenol derivatives synthesized as described above, a phenol derivative having an alkoxymethyl group is particularly preferred in view of the sensitivity and storage stability.

Other preferred examples of the crosslinking agent further include compounds having an N-hydroxymethyl group or an N-alkoxymethyl group, such as alkoxymethylated melamine-based compounds, alkoxymethyl glycoluril-based compounds, and alkoxymethylated urea-based compounds.

As for such compounds, hexamethoxymethylmelamine, hexaethoxymethylmelamine, tetramethoxymethyl glycoluril, 1,3-bismethoxymethyl-4,5-bismethoxyethyleneurea, and bismethoxymethylurea may be exemplified, which are disclosed in EP0133216A, DE3,634,671B and DE3,711,264B, and EP0212482A.

Among these crosslinking agents, particularly preferred are those illustrated below.

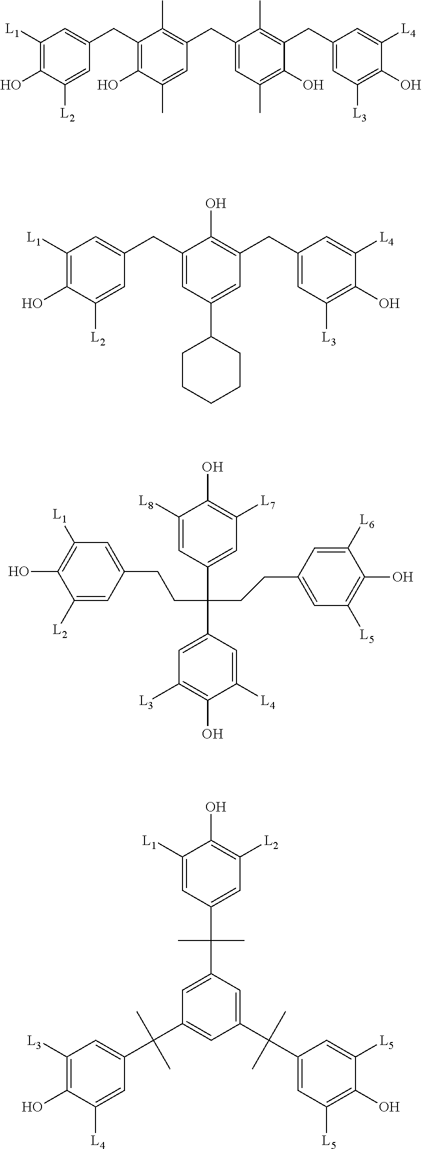

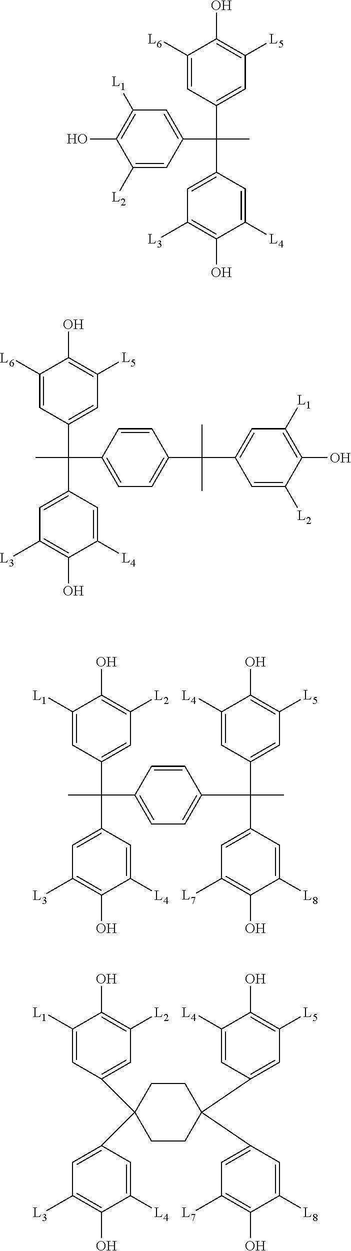

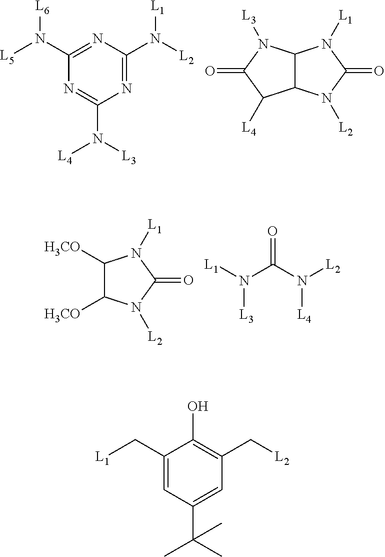

In these formulae, L₁ to L₈ each independently represent a hydrogen atom, a hydroxymethyl group, a methoxymethyl group, an ethoxymethyl group, or an alkyl group having 1 to 6 carbon atoms.

In the present invention, the crosslinking agent is used preferably in an amount of 3 mass % to 65 mass %, and more preferably 5 mass % to 50 mass %, based on the solid content of the negative resist composition. When the amount of the crosslinking agent added is within the range of 3 mass % to 65 mass %, good storage stability of a resist solution can be maintained while preventing deterioration of the residual film ratio and resolution.

In the present invention, the crosslinking agent may be used alone or in combination of two or more thereof. In view of pattern profile, the crosslinking agent is preferably used in combination of two or more thereof.

For example, in the case where another compound, for example, the above-mentioned compound having an N-alkoxymethyl group or the like is used in combination with the phenol derivative, the ratio of the phenol derivative to another compound is in a molar ratio of 100/0 to 20/80, preferably 90/10 to 40/60, and more preferably 80/20 to 50/50.

[4] (D) Basic Compound

The composition of the present invention preferably contains a basic compound, in addition to the components described above, as an acid scavenger. By using the basic compound, the change of performance with aging from exposure to post bake may be reduced. The basic compound is preferably an organic basic compound, and more specific examples thereof include aliphatic amines, aromatic amines, heterocyclic amines, a nitrogen-containing compound having a carboxyl group, a nitrogen-containing compound having a sulfonyl group, a nitrogen-containing compound having a hydroxyl group, a nitrogen-containing compound having a hydroxyphenyl group, an alcoholic nitrogen-containing compound, amide derivatives, and imide derivatives. An amine oxide compound (described in JP2008-102383A) and an ammonium salt (preferably a hydroxide or a carboxylate; more specifically, a tetraalkylammonium hydroxide typified by tetrabutyl ammonium hydroxide is preferred in view of LER) may also be appropriately used. Furthermore, a compound whose basicity is increased by the action of an acid may also be used as a kind of the basic compound.

Specific examples of the amines may include tri-n-butylamine, tri-n-pentylamine, tri-n-octylamine, tri-n-decylamine, triisodecylamine, dicyclohexylmethylamine, tetradecylamine, pentadecylamine, hexadecylamine, octadecylamine, didecylamine, methyloctadecylamine, dimethylundecylamine, N,N-dimethyldodecylamine, methyldioctadecylamine, N,N-dibutylaniline, N,N-dihexylaniline, 2,6-diisopropylaniline, 2,4,6-tri(t-butyl)aniline, triethanolamine, N,N-dihydroxyethylaniline, tris(methoxyethoxyethyl)amine, the compounds exemplified in column 3, line 60 et seq. of U.S. Pat. No. 6,040,112A, 2-[2-{2-(2,2-dimethoxy-phenoxyethoxy)ethyl}-bis-(2-methoxyethyl)]-amine, and compounds (C1-1) to (C3-3) exemplified in paragraph <0066> of US2007/0224539A.

Examples of the compound having a nitrogen-containing heterocyclic structure may include 2-phenylbenzimidazole, 2,4,5-triphenylimidazole, N-hydroxyethylpiperidine, bis(1,2,2,6,6-pentamethyl-4-piperidyl) sebacate, 4-dimethylaminopyridine, antipyrine, hydroxyantipyrine, 1,5-diazabicyclo[4.3.0]-nona-5-ene, and 1,8-diazabicyclo[5.4.0]-undeca-7-ene. The ammonium salt is preferably tetrabutyl ammonium hydroxide.

In addition, a photodecomposable basic compound (a compound which initially exhibits basicity due to the action of the basic nitrogen atom as a base but decomposes upon irradiation with actinic rays or radiation to generate an amphoteric ionic compound having a basic nitrogen atom and an organic acid moiety and resulting from their neutralization in the molecule, is reduced in or deprived of the basicity; for example, onium salts described in JP3577743B, JP2001-215689A, JP2001-166476A, and JP2008-102383A), and a photobase generator (for example, compounds described in JP2010-243773A) may also be appropriately used.

Among these basic compounds, an ammonium salt is preferred in view of improving resolution.

The content of the basic compound used in the present invention is preferably 0.01 mass % to 10 mass %, more preferably 0.03 mass % to 5 mass %, and particularly preferably 0.05 mass % to 3 mass %, based on the total solid content of the composition.

[5] Surfactant

A surfactant may also be added to the composition of the present invention in order to improve the coatability. Examples of the surfactant may include a nonionic surfactant such as polyoxyethylene alkyl ethers, polyoxyethylene alkylallyl ethers, polyoxyethylenepolyoxypropylene block copolymers, sorbitan fatty acid esters, and polyoxyethylene sorbitan fatty acid esters, a fluorine-based surfactant such as FLORAD FC430 (manufactured by Sumitomo 3M Limited), SURFYNOL E1004 (manufactured by Asahi Glass Co., Ltd.), and PF656 and PF6320 manufactured by OMNOVA Solutions Inc., and an organosiloxane polymer.

In the case where the composition of the present invention contains a surfactant, the amount of the surfactant used is preferably 0.0001 mass % to 2 mass %, and more preferably 0.0005 mass % to 1 mass %, based on the total amount of the composition (excluding the solvent).

[6] Organic Carboxylic Acid

The composition of the present invention preferably contains an organic carboxylic compound, in addition to the components described above. Examples of the organic carboxylic compound may include an aliphatic carboxylic acid, an alicyclic carboxylic acid, an unsaturated aliphatic carboxylic acid, an oxycarboxylic acid, an alkoxycarboxylic acid, a ketocarboxylic acid, a benzoic acid derivative, a phthalic acid, a terephthalic acid, an isophthalic acid, a 2-naphthoic acid, a 1-hydroxy-2-naphthoic acid, and a 2-hydroxy-3-naphthoic acid. In the case where the electron beam exposure is carried out in vacuum, an aromatic organic carboxylic acid, above all, for example, a benzoic acid, a 1-hydroxy-2-naphthoic acid, and a 2-hydroxy-3-naphthoic acid are preferred since these acids are less likely to vaporize from the resist film surface to contaminate the inside of a lithography chamber.

The blending amount of the organic carboxylic acid is preferably in the range of 0.01 parts by mass to 10 parts by mass, more preferably 0.01 parts by mass to 5 parts by mass, and still more preferably 0.01 parts by mass to 3 parts by mass, based on 100 parts by mass of the polymer compound (A).

The composition of the present invention, as necessary, may further contain a dye, a plasticizer, a photo-decomposable base compound, a photobase generator, and the like. Examples of these compounds include the compounds described in JP2002-6500A.

Preferred examples of the organic solvent used for the composition of the present invention include ethylene glycol monoethyl ether acetate, cyclohexanone, 2-heptanone, propylene glycol monomethyl ether (PGME, another name: 1-methoxy-2-propanol), propylene glycol monomethyl ether acetate (PGMEA, another name: 1-methoxy-2-acetoxypropane), propylene glycol monomethyl ether propionate, propylene glycol monoethyl ether acetate, methyl 3-methoxypropionate, ethyl 3-ethoxypropionate, methyl β-methoxyisobutyrate, ethyl butyrate, propyl butyrate, methyl isobutyl ketone, ethyl acetate, isoamyl acetate, ethyl lactate, toluene, xylene, cyclohexyl acetate, diacetone alcohol, N-methylpyrrolidone, N,N-dimethylformamide, γ-butyrolactone, N,N-dimethylacetamide, propylene carbonate, and ethylene carbonate. These solvents may be used alone or in combination thereof.

The solid component of the composition of the present invention is dissolved in the solvent, and is dissolved at a solid content concentration preferably in the range of 1 mass % to 40 mass %, more preferably 1 mass % to 30 mass %, and still more preferably 3 mass % to 20 mass %. With a solid content concentration in this range, the above-described film thickness can be achieved.

The present invention also relates to a resist film formed by the composition of the present invention. Such a resist film is formed, for example, by coating the composition of the present invention having the solid content concentration as described above on a support such as a substrate. The composition of the present invention is applied on a substrate using an appropriate coating method such as spin coating, roll coating, flow coating, dip coating, spray coating, or doctor coating. The coating film is pre-baked at 60° C. to 150° C. for 1 minute to 20 minutes, and preferably at 80° C. to 120° C. for 1 minute to 10 minutes to form a resist film. The film thickness of the resist film formed is preferably 10 nm to 200 nm, more preferably 10 nm to 150 nm, and still more preferably 20 nm to 150 nm.

The substrate suitable for the present invention is a silicon substrate or a substrate having provided thereon a metal deposited film or a metal-containing film, and a substrate having provided on the surface thereof a deposited film by Cr, MoSi, TaSi, or an oxide or nitride thereof is more suited.

The present invention also relates to a resist-coated mask blank coated with the thus-obtained resist film. In order to obtain such a resist-coated mask blank, in the case of forming a resist pattern on a photomask blank for the production of a photomask, the transparent substrate to be used is a transparent substrate such as quartz and calcium fluoride. In general, a light-shielding film, an antireflection film, further a phase shift film, and additionally a required functional film such as etching stopper film and etching mask film are stacked on the substrate. As for the material of the functional film, a film containing silicon or a transition metal such as chromium, molybdenum, zirconium, tantalum, tungsten, titanium, and niobium is stacked. Examples of the material used for the outermost layer include a silicon compound material where the main constituent material is a material containing silicon or containing silicon and oxygen and/or nitrogen, a silicon compound material where the main constituent material is the material above which further contains a transition metal, and a transition metal compound material where the main constituent material is a material containing a transition metal, particularly, one or more transition metals selected from chromium, molybdenum, zirconium, tantalum, tungsten, titanium, and niobium, or further containing one or more elements selected from oxygen, nitrogen, and carbon.

The light-shielding film may have a single-layer structure but more preferably has a multilayer structure where a plurality of materials are applied one on another. In the case of a multilayer structure, the film thickness per layer is not particularly limited but is preferably 5 nm to 100 nm, and more preferably 10 nm to 80 nm. The thickness of the entire light-shielding film is not particularly limited but is preferably 5 nm to 200 nm, and more preferably 10 nm to 150 nm

In the case where the pattern formation is carried out using an actinic ray-sensitive or radiation-sensitive resin composition on the photomask blank having the material containing chromium and oxygen or nitrogen in the outermost layer thereof among the materials described above, a so-called undercut shape having a waisted shape near the substrate is likely to be formed in general. However, in the case of using the composition of the present invention, the undercut problem may be improved as compared with the conventional composition.

Subsequently, this resist film is irradiated with actinic rays or radiation (for example, electron beam), then preferably baked (usually at 80° C. to 150° C., more preferably 90° C. to 130° C.), and subsequently developed. In this manner, a good pattern may be obtained. Etching, ion implantation, or the like is appropriately performed by using this pattern as the mask to produce, for example, a semiconductor fine circuit or an imprint mold structure.

Meanwhile, the process for preparing an imprint mold by using the composition of the present invention is described, for example, in JP4109085B, and JP2008-162101A.

The present invention also relates to a resist pattern forming method including exposing the above-described resist film or resist-coated mask blank and developing the exposed resist film or resist-coated mask blank. In the present invention, the exposure is preferably performed using an electron beam or extreme-ultraviolet rays.

Further, the present invention also relates to a photomask obtained by exposing and developing the resist-coated mask blank.

In the production or the like of a precision integrated circuit element, at the exposure on the resist film (a pattern forming step), first, it is preferred to perform patternwise irradiation of an electron beam or extreme ultraviolet (EUV) light on the resist film of the present invention. The exposure is carried out at an exposure dose ranging from about 0.1 μC/cm² to 20 μC/cm² and preferably about 3 μC/cm² to 15 μC/cm² in a case of an electron beam, and an exposure dose ranging from about 0.1 mJ/cm² to 20 mJ/cm² and preferably from about 3 mJ/cm² to 15 mJ/cm² in a case of EUV light. Then, on a hot plate, the film is subjected to post-exposure baking (PEB) at 60° C. to 150° C. for 1 minute to 20 minutes, preferably at 80° C. to 120° C. for 1 minute to 10 minutes, and then is developed, rinsed and dried to form a resist pattern.

The developer may be an alkali developer or an organic developer.

As the alkali developer, use can be made of an alkaline aqueous solution of the followings: inorganic alkalis such as sodium hydroxide, potassium hydroxide, sodium carbonate, sodium silicate, sodium metasilicate, and aqueous ammonia; primary amines such as ethylamine and n-propylamine; secondary amines such as diethylamine and di-n-butylamine; tertiary amines such as triethylamine and methyldiethylamine; alcohol amines such as dimethylethanolamine and triethanolamine; tetraalkylammonium hydroxides such as tetramethylammonium hydroxide, tetraethylammonium hydroxide, tetrapropylammonium hydroxide, tetrabutylammonium hydroxide, tetrapentylammonium hydroxide, tetrahexylammonium hydroxide, tetraoctylammonium hydroxide, ethyltrimethylammonium hydroxide, butyltrimethylammonium hydroxide, methyltriamylammonium hydroxide, and dibutyldipentylammonium hydroxide; quaternary ammonium salts such as trimethylphenylammonium hydroxide, trimethylbenzylammonium hydroxide, and triethylbenzylammonium hydroxide; or cyclic amines such as pyrrole and piperidine.

Furthermore, alcohols or a surfactant may be added in an appropriate amount to the above alkaline aqueous solution.

The alkali concentration of the alkali developer is usually 0.1 mass % to 20 mass %.

The pH of the alkali developer is usually 10.0 to 15.0.

Particularly, an aqueous solution including 2.38 mass % of tetramethylammoniumhydroxyde is preferred.

The organic developer usable in carrying out development is a polar solvent, such as a ketone solvent, an ester solvent, an alcohol solvent, an amide solvent, or an ether solvent, or a hydrocarbon solvent.

Examples of the ketone solvent include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetyl carbinol, acetophenone, methyl naphthyl ketone, isophorone, and propylene carbonate.

Examples of the ester solvent include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, and propyl lactate.

Examples of the alcohol solvent include alcohols such as methyl alcohol, ethyl alcohol, n-propyl alcohol, isopropyl alcohol, n-butyl alcohol, sec-butyl alcohol, 4-methyl-2-pentanol, tert-butyl alcohol, isobutyl alcohol, n-hexyl alcohol, n-heptyl alcohol, n-octyl alcohol, and n-decanol; glycol solvents such as ethylene glycol, diethylene glycol, and triethylene glycol; and glycol ether solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethyl butanol.

Examples of the ether solvent include anisole, dioxane, and tetrahydrofuran in addition to the glycol ether solvents as recited above.

Examples of the amide solvent include N-methyl-2-pyrrolidone, N,N-dimethylacetamide, N,N-dimethylformamide, hexamethylphosphoric triamide, and 1,3-dimethyl-2-imidazolidinone.

Examples of the hydrocarbon solvent include aromatic hydrocarbon solvents such as toluene and xylene, and aliphatic hydrocarbon solvents, such as pentane, hexane, octane, and decane.

The solvents as recited above may be used as mixtures of two or more thereof, or as mixtures with other solvents or water. However, in order to sufficiently exhibit the effect of the present invention, the water content in the entire developer is preferably less than 10 mass %, and it is more preferred that the developer contains substantially no water.

That is, the amount of the organic solvent for the organic developer is preferably from 90 mass % to 100 mass %, more preferably from 95 mass % to 100 mass %, based on the total amount of the developer.

In particular, the organic developer is preferably a developer containing at least one organic solvent selected from the group consisting of a ketone solvent, an ester solvent, an alcohol solvent, an amide solvent, and an ether solvent.

The organic developer may contain a basic compound. Specific examples and preferred examples of the basic compound containable in the developer for use in the present invention are the same as those described above for the basic compound containable in the actinic ray-sensitive or radiation-sensitive resin composition.

If necessary, an appropriate amount of a surfactant can be added to the organic developer.

### EXAMPLES

Hereinafter, the present invention will be described in more detail with reference to examples, but is not limited thereto.

<Synthesis of Polymer Compound (P1)>

25.5 g of p-hydroxystyrene (53.1 mass % propylene glycol monomethyl ether solution), 9.69 g of a compound represented by the following General Formula (X), 2.42 g of a polymerization initiator V-601 (manufactured by Wako Pure Chemical Industries, Ltd.) were dissolved in 31.4 g of propylene glycol monomethyl ether (PGME) (solution 1). 10.8 g of PGME (solution 2) was charged into a reaction vessel, and the solution 2 was heated to 85° C. The solution 1 was added dropwise over 2 hours while maintaining the inside of the reaction vessel at 85° C. under a nitrogen gas atmosphere. The obtained reaction solution was heated and stirred for 4 hours, and was then allowed to cool to room temperature.

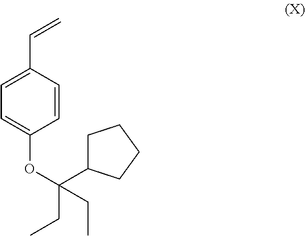 [SMILES: C=Cc1ccc(OC(CC)(CC)C2CCCC2)cc1]

Then, 33 g of acetone was added to the reaction solution which had been allowed to cool to room temperature, so the reaction solution was diluted. The diluted reaction solution was added dropwise to 1000 g of heptane/ethyl acetate (mass ratio)=8/2 to precipitate a polymer, followed by filtration. Thereafter, the filtered polymer (solid) was subjected to drying under reduced pressure to give 31.31 g of a polymer compound (P1).

<Synthesis of Polymer Compound (P2)>

20 g of poly(p-hydroxystyrene) (VP2500, manufactured by Nippon Soda Co., Ltd.) was dissolved in 120 mL of toluene, to which 6.2 g of prop-1-en-2-ylcyclohexane was then added. The resulting solution was cooled to 5° C. or lower. Then, 0.5 g of methanesulfonic acid was added thereto, and the reaction system was stirred for 8 hours while maintaining the temperature at 5° C. or lower. A 1N NaOH aqueous solution was added portionwise to the solution after stirring which was then neutralized. The solution after neutralization was transferred to a funnel, to which 100 mL of ethyl acetate and 100 mL of distilled water were further added, followed by stirring, and the aqueous layer was removed. Thereafter, the organic layer was washed 5 times with 200 mL of distilled water, and then concentrated to give a crude product. A toluene solution of the crude product was added dropwise to 3 L of hexane to precipitate a polymer. The precipitated polymer was collected by filtration, and dried under vacuum to give 10.6 g of a polymer compound (P2).

<Synthesis of Polymer Compounds (P3) to (P12) and Comparative Polymer Compounds (P1) to (P4)>

Other polymer compounds (P3) to (P12) and comparative polymer compounds (P1) to (P4) were synthesized in the same manner as in the polymer compounds (P1) and (P2).

For the obtained polymer compounds, the composition ratio (molar ratio) of the polymer compound was calculated by ¹H-NMR measurement. In addition, the weight average molecular weight (Mw: in terms of polystyrene), number average molecular weight (Mn: in terms of polystyrene), and polydispersity (Mw/Mn, hereinafter also referred to as “PDI”) of each polymer compound were calculated by GPC (solvent: THF) measurement. With respect to the weight average molecular weight and polydispersity, the chemical formula and the composition ratio of each polymer compound are given therewith in Table 1 and Table 2 below.

TABLE 1

| | | | Weight | |
|---|---|---|---|---|
| | | Composition | average | |
| Polymer | | ratio | molecular | |
| compound | Chemical formula | (molar ratio) | weight | Polydispersity |
| Polymer Compound (P1) | 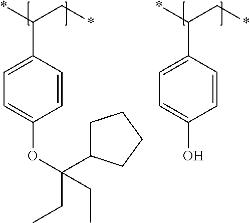 | 25/75 | 9100 | 1.5 |
| Polymer compound (P2) | 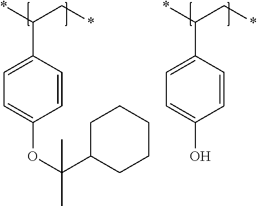 | 30/70 | 9200 | 1.1 |
| Polymer compound (P3) | 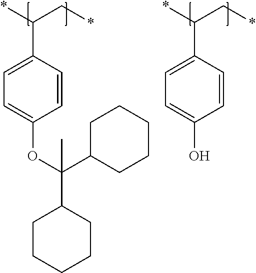 | 25/75 | 4000 | 1.1 |
| Polymer compound (P4) | 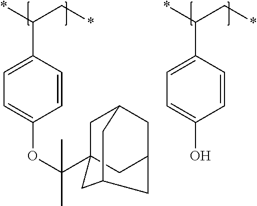 | 30/70 | 9300 | 1.1 |
| Polymer compound (P5) | 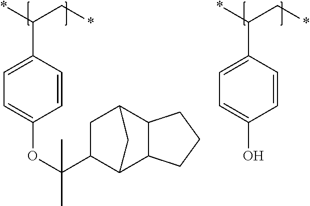 | 20/80 | 9200 | 1.1 |
| Polymer compound (P6) | 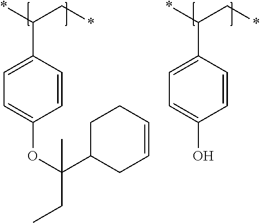 | 20/70/10 | 9100 | 1.1 |
| | 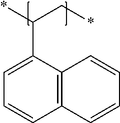 | | | |
| Polymer compound (P7) | 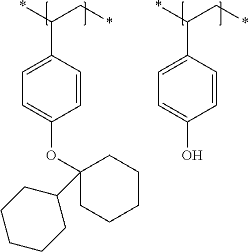 | 30/70 | 6000 | 1.1 |
| Polymer compound (P8) | 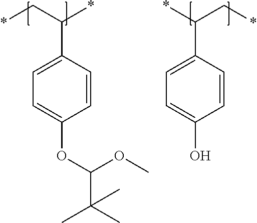 | 10/7/10/10 | 8000 | 1.5 |
| | 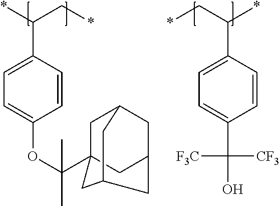 | | | |

TABLE 2

| | | | Weight | |
|---|---|---|---|---|
| | | Composition | average | |
| Polymer | | ratio | molecular | |
| compound | Chemical formula | (molar ratio) | weight | Polydispersity |
| Polymer compound (P9) | 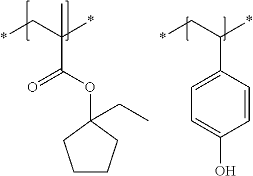 | 20/50/20/10 | 5000 | 1.5 |
| | 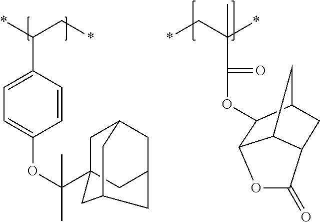 | | | |
| Polymer compound (P10) | 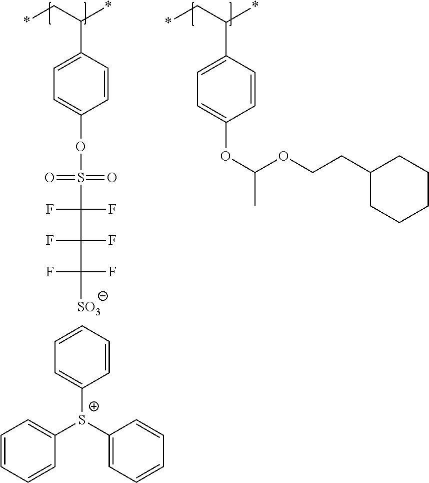 | 10/20/50/20 | 9900 | 1.5 |
| | 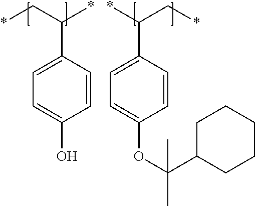 | | | |
| Polymer compound (P11) | 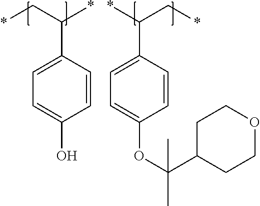 | 70/30 | 5000 | 1.5 |
| Polymer compound (P12) | 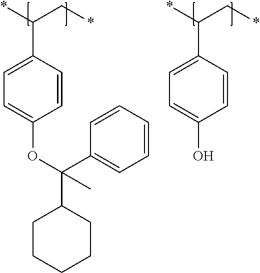 | 30/70 | 5000 | 1.1 |
| Polymer compound (P13) | 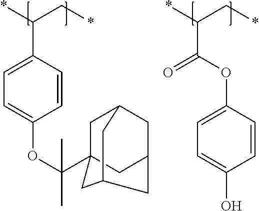 | 30/50/10/10 | 6000 | 1.5 |
| | 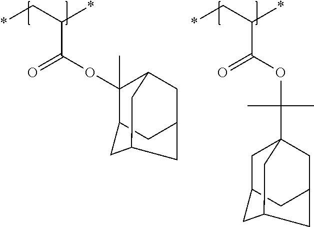 | | | |
| Comparative polymer compound (P1) | 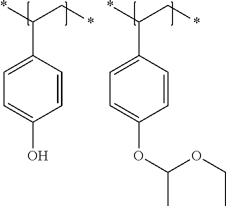 | 40/60 | 8800 | 1.1 |
| Comparative polymer compound (P2) | 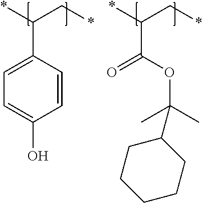 | 60/40 | 9100 | 1.5 |
| Comparative polymer compound (P3) | 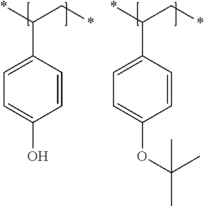 | 60/40 | 6000 | 1.5 |
| Comparative polymer compound (P4) | 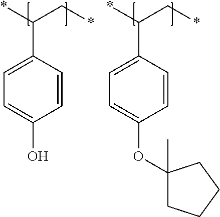 | 70/30 | 9900 | 1.9 |

### Example 1P

### (1) Preparation of Support

A Cr oxide-deposited 6-inch wafer (a wafer subjected to a treatment of forming a shielding film, which is used for conventional photomask) was prepared.

(2) Preparation of Actinic Ray-Sensitive or Radiation-Sensitive Resin Composition (Preparation of Composition P1)

| | |
|---|---|
| Polymer compound (P1) | 0.60 g |
| Photoacid generator (z42) | 0.12 g |
| (Structural formula below) | |
| Tetrabutyl ammonium hydroxide | 0.002 g |
| (Basic compound) | |
| Surfactant PF6320 (manufactured | 0.001 g |
| by OMNOVA Solutions Inc.) | |
| Propylene glycol monomethyl | 9.0 g |
| ether acetate (Solvent) | |

The ingredients above were blended, and the mixture was microfiltered through a membrane filter having a pore size of 0.04 μm to obtain a composition P1.

(3) Preparation of Resist Film

The composition P1 was coated on the above-described 6-inch wafer by using a spin coater, MARK 8, manufactured by Tokyo Electron Ltd., and dried on a hot plate at 110° C. for 90 seconds to obtain a resist film having a thickness of 100 nm. That is, a resist-coated mask blank was obtained.

(4) Production of Positive Resist Pattern

This resist film was patternwise irradiated with an electron beam by using an electron beam lithography device (HL750 manufactured by Hitachi, Ltd., accelerating voltage: 50 KeV). After the irradiation, the resist film was heated on a hot plate at 120° C. for 90 seconds, dipped in an aqueous solution of 2.38 mass % tetramethylammonium hydroxide (TMAH) for 60 seconds, rinsed with water for 30 seconds and dried to obtain a resist pattern.

(5) Resist Pattern Evaluation

The obtained resist pattern was evaluated for the sensitivity, resolution, pattern profile, line edge roughness (LER), and dry etching resistance according to the following methods.

[Sensitivity]

The cross-sectional profile of the resist pattern obtained was observed using a scanning electron microscope (S-4300, manufactured by Hitachi, Ltd.). An exposure dose when resolving a resist pattern with a line width of 100 nm (line:space=1:1) was taken as the sensitivity (unit: μC/cm²). A smaller value indicates higher sensitivity.

[Resolution Evaluation (LS)]

The limiting resolution (the minimum line width when the line and the space (line:space=1:1) were separated and resolved) at the exposure dose (dose of electron beam irradiation) giving the sensitivity above was taken as the LS resolution (unit: nm).

[Resolution Evaluation (IL)]

The limiting resolution (the minimum line width when the line and the space (line:space=1:>100) were separated and resolved) at a minimum irradiation dose when resolving an isolated line pattern with a line width of 100 nm (line:space=1:>100) was taken as the IL resolution (unit: nm).

[Pattern Profile Evaluation]

The cross-sectional profile of the line pattern with a line width of 100 nm (L/S=1/1) at the exposure dose (dose of electron beam irradiation) giving the sensitivity above was observed by a scanning electron microscope (S-4300, manufactured by Hitachi, Ltd.). The cross-sectional profile of the line pattern was rated “forward taper” when the ratio represented by [line width in the bottom part (base part) of line pattern/line width in the middle part of line pattern (the position of half the height of line pattern)] is 1.5 or more, rated “slightly forward taper” when the ratio above is from 1.2 to less than 1.5, and rated “rectangle” when the ratio is less than 1.2.

[Line Edge Roughness (LER)]

A line pattern (L/S=1/1) having a line width of 100 nm was formed with the exposure dose (dose of electron beam irradiation) giving the sensitivity above. Then, at arbitrary 30 points included in its longitudinal 50 μm region, the distance from the reference line where the edge should be present was measured using a scanning electron microscope (S-9220, manufactured by Hitachi, Ltd.). The standard deviation of the measured distances was determined, and 3σ was computed. A smaller value indicates better performance.

[Dry Etching Resistance Evaluation]

An unexposed resist film was subjected to dry etching for 30 seconds by using a dry etching apparatus (HITACHI U-621, etching gas: an Ar/C₄F₆/O₂ gas (a mixed gas in a volume ratio of 100/4/2)). Thereafter, the residual resist film ratio was measured, and dry etching resistance was evaluated based on the following evaluation criteria.

(Evaluation Criteria)

Very good: Residual film ratio of 95% or more.

Good: From 90% to less than 95%.

Bad: Less than 90%.

### Examples 2P to 23P and Comparative Examples 1P to 4P

Compositions P2 to P23 and comparative compositions P1 to P4 were prepared in the same manner as in the composition P1, except that components used in the preparation of composition P1 were changed to components described in Tables 3 and 4 below. Positive resist patterns were prepared using each composition and each comparative composition thus obtained. Each resist pattern obtained was evaluated for the sensitivity, resolution, pattern profile, line edge roughness (LER), and dry etching resistance. The results are shown in Table 5 below.

TABLE 3
(Electron Beam Exposure; Positive)

| | Polymer | Photoacid | Basic | |
|---|---|---|---|---|
| Composition | compound | generator | compound | Solvent |
| P1 | P1 | z42 | B1 | S1 |
| | (0.6 g) | (0.12 g) | (0.002 g) | (9.0 g) |
| P2 | P2 | z42 | B1 | S2/S1 |
| | (0.6 g) | (0.12 g) | (0.002 g) | (5.0 g/4.0 g) |
| P3 | P3 | z42 | B1 | S2/S3 |
| | (0.6 g) | (0.12 g) | (0.002 g) | (5.0 g/4.0 g) |
| P4 | P4 | z42 | B1 | S2/S1 |
| | (0.6 g) | (0.12 g) | (0.002 g) | (5.0 g/4.0 g) |
| P5 | P5 | z42 | B1 | S2/S1 |
| | (0.6 g) | (0.12 g) | (0.002 g) | (5.0 g/4.0 g) |
| P6 | P6 | z42 | B1 | S2/S4 |
| | (0.6 g) | (0.12 g) | (0.002 g) | (5.0 g/4.0 g) |
| P7 | P7 | z42 | B1 | S2/S5 |
| | (0.6 g) | (0.12 g) | (0.002 g) | (5.0 g/4.0 g) |
| P8 | P8 | z42 | B1 | S2/S1 |
| | (0.6 g) | (0.12 g) | (0.002 g) | (5.0 g/4.0 g) |
| P9 | P9 | z42 | B1 | S2/S3 |
| | (0.6 g) | (0.12 g) | (0.002 g) | (5.0 g/4.0 g) |
| P10 | P10 | None | B1 | S1/S3 |
| | (0.72 g) | | (0.002 g) | (5.0 g/4.0 g) |
| P11 | P11 | z42 | B1 | S2/S3 |
| | (0.6 g) | (0.12 g) | (0.001 g) | (5.0 g/4.0 g) |
| P12 | P4 | z2 | B2 | S2/S7 |
| | (0.6 g) | (0.12 g) | (0.008 g) | (5.0 g/4.0 g) |
| P13 | P4/P5 | z37 | B4 | S2/S1 |
| | (0.3 g/ | (0.12 g) | (0.002 g) | (5.0 g/4.0 g) |
| | 0.3 g) | | | |
| P14 | P4 | z45 | B5 | S2/S1 |
| | (0.6 g) | (0.12 g) | (0.002 g) | (5.0 g/4.0 g) |
| P15 | P4 | z49/z58 | B6 | S2/S1 |
| | (0.6 g) | (0.06 g/ | (0.002 g) | (5.0 g/4.0 g) |
| | | 0.06 g) | | |
| P16 | P4 | z61 | B3 | S2/S1 |
| | (0.6 g) | (0.12 g) | (0.002 g) | (5.0 g/4.0 g) |
| P17 | P4 | z63 | B1 | S2/S1 |
| | (0.6 g) | (0.12 g) | (0.002 g) | (5.0 g/4.0 g) |
| P18 | P4 | z65 | B1 | S2/S1 |
| | (0.6 g) | (0.12 g) | (0.002 g) | (5.0 g/4.0 g) |
| P19 | P4 | z5 | B1 | S2/S1 |
| | (0.6 g) | (0.12 g) | (0.002 g) | (5.0 g/4.0 g) |
| P20 | P4 | z8 | B1/B6 | S2/S1 |
| | (0.6 g) | (0.12 g) | (0.001 g/ | (5.0 g/4.0 g) |
| | | | 0.001 g) | |
| P21 | P4 | z66 | B1 | S2/S1 |
| | (0.6 g) | (0.12 g) | (0.002 g) | (5.0 g/4.0 g) |
| P22 | P12 | z42 | B1 | S1 |
| | (0.6 g) | (0.12 g) | (0.002 g) | (9.0 g) |
| P23 | P13 | z42 | B1 | S1 |
| | (0.6 g) | (0.12 g) | (0.002 g) | (9.0 g) |

TABLE 4
(Electron Beam Exposure; Positive)

| | | Photoacid | Basic | |
|---|---|---|---|---|
| Composition | Polymer compound | generator | compound | Solvent |
| Comparative | Comparative polymer | z2 | B2 | S1 |
| composition | compound (P1) | (0.12 g) | (0.002 g) | (9.0 g) |
| P1 | (0.6 g) | | | |
| Comparative | Comparative polymer | z2 | B2 | S1 |
| composition | compound (P2) | (0.12 g) | (0.002 g) | (9.0 g) |
| P2 | (0.6 g) | | | |
| Comparative | Comparative polymer | z2 | B2 | S1 |
| composition | compound (P3) | (0.12 g) | (0.002 g) | (9.0 g) |
| P3 | (0.6 g) | | | |
| Comparative | Comparative polymer | z2 | B2 | S1 |
| composition | compound (P4) | (0.12 g) | (0.002 g) | (9.0 g) |
| P4 | (0.6 g) | | | |

Components listed in Tables 3 and 4 other than the aforementioned components will be described below.

[Acid Generator (Compound (B))]

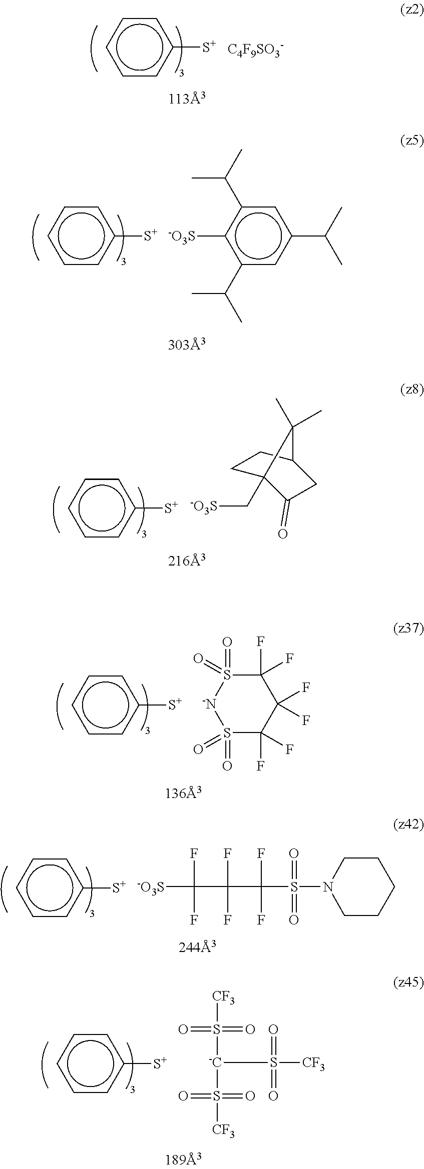

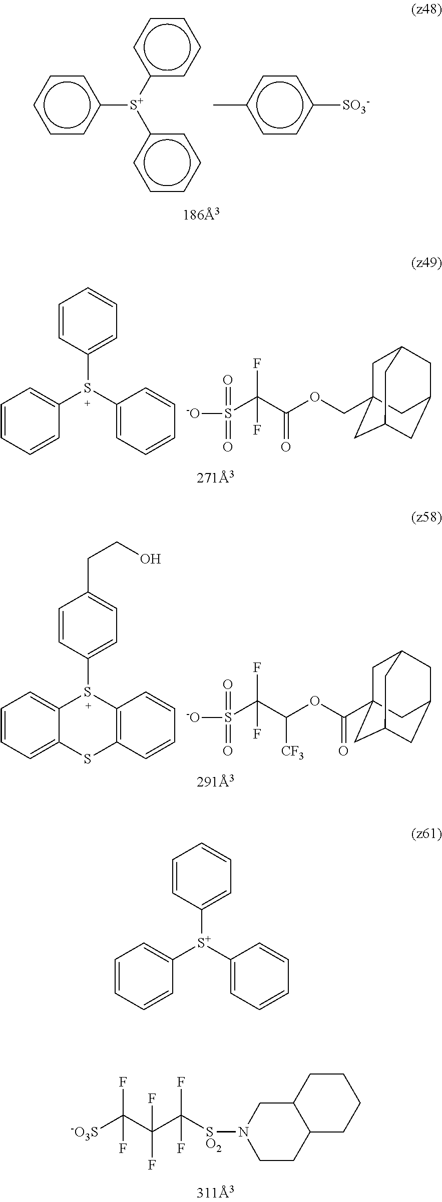

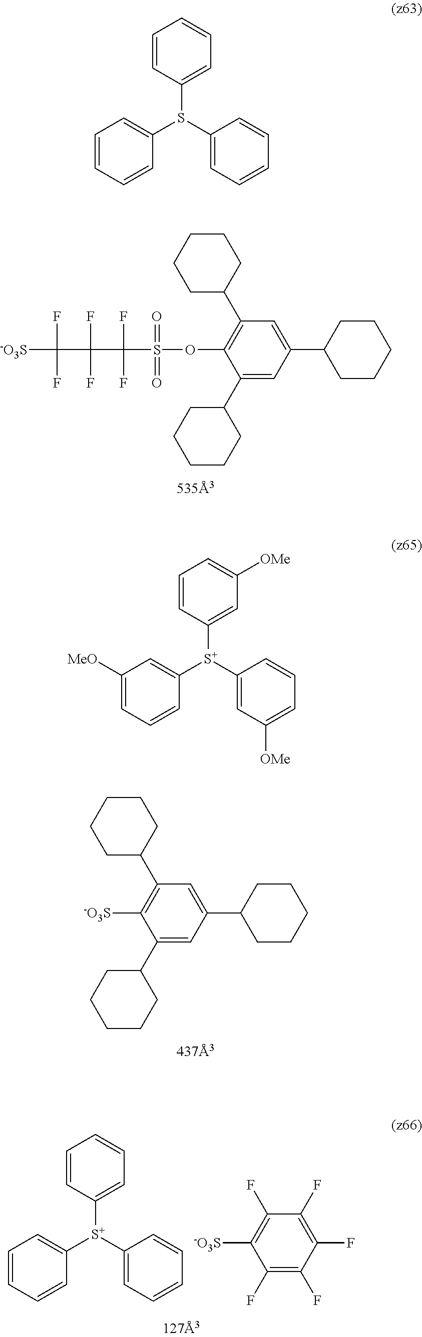

[Basic Compound]

B1: Tetrabutylammonium hydroxide

B2: Tri(n-octyl)amine

B3: 2,4,5-triphenylimidazole

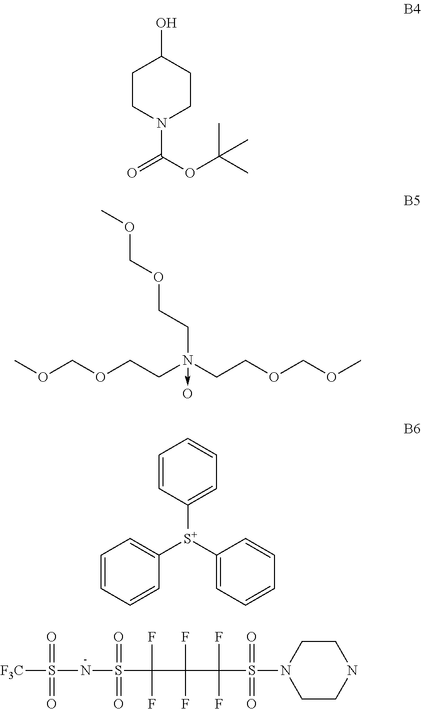

[Solvent]

S1: Propylene glycol monomethyl ether acetate (1-methoxy-2-acetoxypropane)

S2: Propylene glycol monomethyl ether (1-methoxy-2-propanol)

S3: 2-Heptanone

S4: Ethyl lactate

S5: Cyclohexanone

S6: γ-Butyrolactone

S7: Propylene carbonate

TABLE 5
(Electron Beam Exposure; Positive)

| | | | LS | IL | | | Dry |
|---|---|---|---|---|---|---|---|
| | | Sensitivity | Resolution | Resolution | Pattern | LER | etching |
| Example | Composition | (μC/cm²) | (nm) | (nm) | profile | (nm) | resistance |
| 1P | P1 | 10.8 | 50 | 45 | Rectangle | 4.5 | Good |
| 2P | P2 | 10.8 | 50 | 45 | Rectangle | 4.5 | Good |
| 3P | P3 | 10.8 | 50 | 45 | Rectangle | 4.5 | Good |
| 4P | P4 | 10.7 | 50 | 45 | Rectangle | 4.5 | Very good |
| 5P | P5 | 10.8 | 50 | 45 | Rectangle | 4.5 | Very good |
| 6P | P6 | 10.8 | 50 | 45 | Rectangle | 4.5 | Good |
| 7P | P7 | 10.7 | 50 | 45 | Rectangle | 4.5 | Good |
| 8P | P8 | 11.8 | 50 | 45 | Rectangle | 4.5 | Very good |
| 9P | P9 | 11.9 | 50 | 45 | Rectangle | 4.5 | Very good |
| 10P | P10 | 11.8 | 50 | 45 | Rectangle | 4.5 | Good |
| 11P | P11 | 11.8 | 50 | 45 | Rectangle | 4.5 | Good |
| 12P | P12 | 10.8 | 55 | 55 | Rectangle | 5.0 | Very good |
| 13P | P13 | 10.7 | 55 | 55 | Rectangle | 5.0 | Very good |
| 14P | P14 | 10.8 | 55 | 55 | Rectangle | 5.0 | Very good |
| 15P | P15 | 10.8 | 50 | 50 | Rectangle | 5.0 | Very good |
| 16P | P16 | 10.6 | 50 | 45 | Rectangle | 5.0 | Very good |
| 17P | P17 | 10.8 | 50 | 45 | Rectangle | 4.5 | Very good |
| 18P | P18 | 10.6 | 50 | 45 | Rectangle | 4.5 | Very good |
| 19P | P19 | 10.5 | 50 | 45 | Rectangle | 4.5 | Very good |
| 20P | P20 | 10.5 | 55 | 50 | Rectangle | 4.5 | Very good |
| 21P | P21 | 10.5 | 55 | 55 | Rectangle | 4.5 | Very good |
| 22P | P22 | 10.8 | 50 | 45 | Rectangle | 4.5 | Good |
| 23P | P23 | 10.8 | 50 | 45 | Rectangle | 4.5 | Very good |
| Comparative | Comparative | 12.9 | 70 | 80 | Forward | 6.5 | Bad |
| Example 1P | composition | | | | taper | | |
| | P1 | | | | | | |
| Comparative | Comparative | 12.9 | 70 | 80 | Slightly | 6.0 | Bad |
| Example 2P | composition | | | | forward | | |
| | P2 | | | | taper | | |
| Comparative | Comparative | 12.9 | 70 | 80 | Forward | 6.5 | Bad |
| Example 3P | composition | | | | taper | | |
| | P3 | | | | | | |
| Comparative | Comparative | 12.9 | 60 | 70 | Slightly | 6.0 | Good |
| Example 4P | composition | | | | forward | | |
| | P4 | | | | taper | | |

From the results shown in Table 5, it can be seen that excellent sensitivity, resolution, pattern profile, LER, and dry etching resistance are achieved according to the composition of the present invention.

### Examples 1Q to 8Q and Comparative Examples 1Q to 4Q

### Preparation of Compositions

The components listed in Tables 3 and 4 were blended in amounts listed in Tables 3 and 4, and filtered through a polytetrafluoroethylene filter having a pore size of 0.04 μm to prepare compositions P1 to P3, P10, P12, and P15 to P17.

(Resist Evaluation)

Each composition prepared was uniformly applied on a hexamethyldisilazane-treated silicon substrate by using a spin coater and dried under heating on a hot plate at 100° C. for 60 seconds to form a resist film having a thickness of 0.05 μm.

The obtained resist film was evaluated for the sensitivity, resolution, pattern profile, line edge roughness (LER), and dry etching resistance according to the following methods.

[Sensitivity]

The obtained resist film was exposed to EUV light (wavelength: 13 nm) through a reflection type mask having a 1:1 line-and-space pattern with a line width of 100 nm by changing the exposure dose in steps of 0.1 mJ/cm² in the range of 0 mJ/cm² to 20.0 mJ/cm², then baked at 110° C. for 90 seconds and developed with an aqueous 2.38 mass % tetramethylammonium hydroxide (TMAH) solution.

The exposure dose when reproducing a line-and-space (L/S=1/1) mask pattern with a line width of 100 nm was taken as the sensitivity (unit: μC/cm²). A smaller value indicates higher sensitivity.

[Resolution Evaluation (LS)]

The limiting resolution (the minimum line width when the line and the space (line:space=1:1) were separated and resolved) at the exposure dose giving the sensitivity above was taken as the LS resolution (unit: nm).

[Pattern Profile Evaluation]

The cross-sectional profile of the line pattern with a line width of 100 nm (L/S=1/1) at the exposure dose giving the sensitivity above was observed by a scanning electron microscope (S-4300, manufactured by Hitachi, Ltd.). The cross-sectional profile of the line pattern was rated “forward taper” when the ratio represented by [line width in the bottom part (base part) of line pattern/line width in the middle part of line pattern (the position of half the height of line pattern)] is 1.5 or more, rated “slightly forward taper” when the ratio above is from 1.2 to less than 1.5, and rated “rectangle” when the ratio is less than 1.2.

[Line Edge Roughness (LER)]

With a line pattern (L/S=/1) having a line width of 100 nm at the exposure dose giving the sensitivity above, at arbitrary 30 points included in its longitudinal 50 μm region, the distance from the reference line where the edge should be present was measured using a scanning electron microscope (S-9220, manufactured by Hitachi, Ltd.). The standard deviation of the measured distances was determined, and 3a was computed. A smaller value indicates better performance.

[Dry Etching Resistance Evaluation]

An unexposed resist film was subjected to dry etching for 30 seconds by using a dry etching apparatus (HITACHI U-621, etching gas: an Ar/C₄F₆/O₂ gas (a mixed gas in a volume ratio of 100/4/2)). Thereafter, the residual resist film ratio was measured, and dry etching resistance was evaluated based on the following evaluation criteria.

(Evaluation Criteria)

Very good: Residual film ratio of 95% or more.

Good: From 90% to less than 95%.

Bad: Less than 90%.

The evaluation results are shown in Table 6 below.

TABLE 61
(EUV Exposure; Positive)

| | | | | | | Dry |
|---|---|---|---|---|---|---|
| | | Sensitivity | Resolution | Pattern | LER | etching |
| Example | Composition | (mJ/cm²) | (nm) | profile | (nm) | resistance |
| 1Q | P1 | 10.8 | 45 | Rectangle | 4.5 | Good |
| 2Q | P2 | 10.8 | 45 | Rectangle | 4.5 | Good |
| 3Q | P3 | 10.8 | 45 | Rectangle | 4.5 | Good |
| 4Q | P10 | 11.5 | 45 | Rectangle | 4.5 | Good |
| 5Q | P12 | 10.8 | 50 | Rectangle | 5.0 | Very good |
| 6Q | P15 | 10.8 | 45 | Rectangle | 5.0 | Very good |
| 7Q | P16 | 10.7 | 45 | Rectangle | 5.0 | Very good |
| 8Q | P17 | 10.8 | 45 | Rectangle | 4.5 | Very good |
| Comparative | Comparative | 12.9 | 70 | Forward | 6.5 | Bad |
| Example 1Q | composition | | | taper | | |
| | P1 | | | | | |
| Comparative | Comparative | 12.9 | 70 | Slightly | 6.0 | Bad |
| Example 2Q | composition | | | forward | | |
| | P2 | | | taper | | |
| Comparative | Comparative | 12.9 | 70 | Forward | 6.5 | Bad |
| Example 3Q | composition | | | taper | | |
| | P1 | | | | | |
| Comparative | Comparative | 12.9 | 60 | Slightly | 6.0 | Good |
| Example 4Q | composition | | | forward | | |
| | P2 | | | taper | | |

From the results shown in Table 6, it can be seen that excellent sensitivity, resolution, pattern profile, line edge roughness (LER), and dry etching resistance are achieved according to the composition of the present invention.

Further, even in the case of changing the developer to an organic developer (butyl acetate) in Examples 1Q to 8Q, the composition of the present invention was confirmed to provide good resist performance similar to the case of the alkali developer.

What is claimed is:

1. An actinic ray-sensitive or radiation-sensitive resin composition, comprising:
(A) a polymer compound having a structure in which a hydrogen atom of a phenolic hydroxyl group is substituted by a group represented by General Formula (I) below; and
(B) a compound capable of generating an acid upon irradiation with actinic rays or radiation, 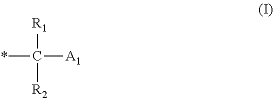
wherein in General Formula (I),
A₁ represents an alicyclic group having 3 to 12 carbon atoms which may have a heteroatom,
R₁ and R₂ each independently represent a hydrocarbon group, or R₁ and R₂ may be bonded to each other to form a ring, and
* indicates a binding site to an oxygen atom of the phenolic hydroxyl group.

2. The actinic ray-sensitive or radiation-sensitive resin composition according to claim 1, wherein the polymer compound (A) includes a repeating unit represented by General Formula (I) below, 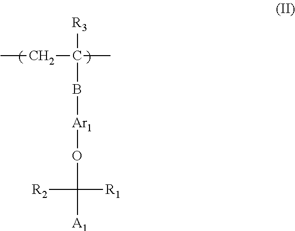
wherein in General Formula (II),
A₁ represents an alicyclic group having 3 to 12 carbon atoms which may have a heteroatom,
R₁ and R₂ each independently represent a hydrocarbon group, or R₁ and R₂ may be bonded to each other to form a ring,
Ar₁ represents an arylene group,
B represents a single bond or a divalent organic group, and
R₃ represents a hydrogen atom, a methyl group which may have a substituent, or a halogen atom.

3. The actinic ray-sensitive or radiation-sensitive resin composition according to claim 2, wherein the polymer compound (A) includes a repeating unit represented by General Formula (II′) below, 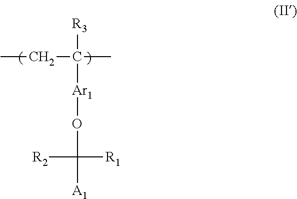
wherein in General Formula (II′),
A₁ represents an alicyclic group having 3 to 12 carbon atoms which may have a heteroatom,
R₁ and R₂ each independently represent a hydrocarbon group, or R₁ and R₂ may be bonded to each other to form a ring,
Ar₁ represents an arylene group, and
R₃ represents a hydrogen atom, a methyl group which may have a substituent, or a halogen atom.

4. The actinic ray-sensitive or radiation-sensitive resin composition according to claim 1, wherein the polymer compound (A) includes a repeating unit represented by General Formula (III) below, 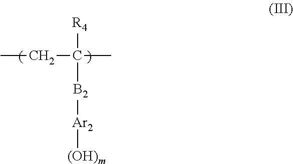
wherein in General Formula (III),
R₄ represents a hydrogen atom, a methyl group which may have a substituent, or a halogen atom,
B₂ represents a single bond or a divalent organic group,
Ar₂ represents an arylene group, and
m represents an integer of 1 or more.

5. The actinic ray-sensitive or radiation-sensitive resin composition according to claim 3, wherein the polymer compound (A) includes a repeating unit represented by General Formula (III) below, 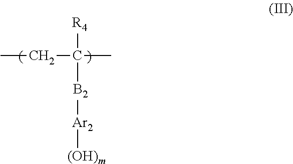
wherein in General Formula (III),
R⁴ represents a hydrogen atom, a methyl group which may have a substituent, or a halogen atom,
B₂ represents a single bond or a divalent organic group,
Ar₂ represents an arylene group, and
m represents an integer of 1 or more.

6. The actinic ray-sensitive or radiation-sensitive resin composition according to claim 4, wherein the polymer compound (A) includes a repeating unit represented by General Formula (III′) below, 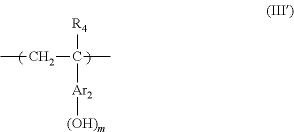
wherein in General Formula (III′),
R₄ represents a hydrogen atom, a methyl group which may have a substituent, or a halogen atom,
Ar₂ represents an arylene group, and
m represents an integer of 1 or more.

7. The actinic ray-sensitive or radiation-sensitive resin composition according to claim 5, wherein the polymer compound (A) includes a repeating unit represented by General Formula (III′) below, 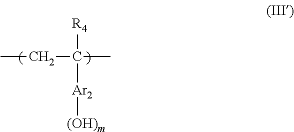
wherein in General Formula (III′),
R₄ represents a hydrogen atom, a methyl group which may have a substituent, or a halogen atom,
Ar₂ represents an arylene group, and
m represents an integer of 1 or more.

8. A resist film formed by the actinic ray-sensitive or radiation-sensitive resin composition according to claim 1.

9. The resist film according to claim 8, which has a film thickness of 10 nm to 150 nm.

10. A resist-coated mask blank having the resist film according to claim 8.

11. A resist pattern forming method, comprising:
exposing the resist film according to claim 8; and
developing the exposed resist film.

12. A resist pattern forming method, comprising:
exposing the resist-coated mask blank according to claim 10; and
developing the exposed resist-coated mask blank.

13. The resist pattern forming method according to claim 11, wherein the exposure is carried out using an electron beam or extreme ultraviolet rays.

14. The resist pattern forming method according to claim 12, wherein the exposure is carried out using an electron beam or extreme ultraviolet rays.

15. A photomask obtained by exposing and developing the resist-coated mask blank according to claim 10.
